(19) United States
(12) Patent Application Publication
(10) Pub. No.: US 2026/0182372 A1
(43) Pub. Date: Jun. 25, 2026

(54) PACKAGE COMPATIBLE WITH PACKAGE ASSEMBLY INCLUDING COMPONENTS HAVING AN OFFSET CONFIGURATION

(71) Applicant: QUALCOMM Incorporated, San Diego, CA (US)

(72) Inventors: Rajneesh KUMAR, San Diego, CA (US); Aniket PATIL, San Diego, CA (US); Zhijie WANG, San Diego, CA (US); Manuel ALDRETE, Encinitas, CA (US); Piyush GUPTA, San Diego, CA (US)

(21) Appl. No.: 19/225,911

(22) Filed: Jun. 2, 2025

Related U.S. Application Data
(60) Provisional application No. 63/736,387, filed on Dec. 19, 2024.

(51) Int. Cl. H01L 23/373; H01L 21/56; H01L 23/00; H01L 23/31; H01L 23/538; H01L 25/00; H01L 25/16

(52) U.S. Cl. CPC H10W 40/258; H10W 70/611; H10W 74/01; H10W 74/111; H10W 90/00; H10W 90/401; H10W 72/072; H10W 72/07236; H10W 72/073; H10W 72/07338; H10W 72/877; H10W 74/15; H10W 90/724; H10W 90/734; H10W 90/736

(57) ABSTRACT

A package includes a first substrate having first contacts on a first side of the first substrate and includes a first die electrically coupled to the first contacts. The first die is configured to be coupled to a heat sink such that a portion of the heat sink is positioned above a portion of the first die. The package further includes a second substrate electrically coupled to the first substrate. The second substrate has first contacts on a first side of the second substrate that is opposite to a second side of the second substrate that faces the first side of the first substrate. The first contacts of the second substrate are configured to be electrically coupled to a second die such that the second die is horizontally adjacent to the heat sink.

### CROSS-REFERENCE TO RELATED APPLICATIONS

The present application claims the benefit of the commonly owned U.S. Provisional Patent Application No. 63/736,387 (Atty. Dkt. No. 2500672P1), filed Dec. 19, 2024, and entitled “OFFSET PACKAGE-ON-PACKAGE DEVICE INCLUDING MULTIPLE COMPONENTS,” which is incorporated herein by reference in its entirety.

### FIELD

Various features relate to integrated device packages, and more particularly, to a package or a package assembly, such as a package-on-package (POP).

### DESCRIPTION OF RELATED ART

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

In the context of integrated circuit (IC) packaging, an “integrated device package” (or simply a “package”) refers to an arrangement of one or more ICs or devices with additional components that facilitate operation of the ICs or devices. For example, the additional components retain and protect the ICs and/or the devices. The additional components often electrically connect the ICs or devices to one another and include package contacts to enable the integrated device package to be connected to other circuits or devices. The components and the ICs and/or devices coupled together in a package can be configured to perform various electrical functions. Additionally, multiple packages can be electrically coupled to form an arrangement which may be referred to as a “package assembly.”

In state-of-the-art electronic devices, there is generally an expectation that integrated device packages have a small form factor, a low cost, a tight power budget, and high performance. These various goals are often in conflict. For example, based on an ongoing demand for improved packages, many package improvements focus on goals such as reducing the dimensions of the package, increasing the performance of the package or the IC devices therein, increasing the efficiency of the package or the IC devices, reducing the cost of the package or the IC devices therein, or combinations of the above. Unfortunately, it is often the case that improvements to one of these goals comes at the cost of one or more of the others. For example, a typical conventional package-on-package (POP) configuration includes multiple packages, such as a first package including a logic die and a second package including a memory die, stacked one on top of another, with the center of the packages being vertically aligned, to achieve a small form factor and short signal routing. However, reducing package size can exacerbate heat dissipation concerns because of the compact and stacked configuration, which can lead to performance throttling to limit heat generation. To improve heat dissipation, a heat sink can be added to the stack; however, the addition of the heat sink to the stack can increase a vertical dimension of the stack, increase signal routing lengths, and reduce interconnect density.

### SUMMARY

Various features relate to packages.

One example provides a package that includes a first substrate having first contacts on a first side of the first substrate. The package also includes a first die electrically coupled to a first set of contacts of the first contacts on the first side of the first substrate. The first die is configured to be coupled to a heat sink such that at least a portion of the heat sink is positioned vertically above at least a portion of the first die. The package further includes a second substrate above and electrically coupled to the first substrate. The second substrate having first contacts on a first side of the second substrate that is opposite to a second side of the second substrate that faces the first side of the first substrate. The first contacts of the second substrate are configured to be electrically coupled to a second die such that the second die is horizontally adjacent to the heat sink.

Another example provides a method of fabrication that includes providing a first substrate having first contacts on a first side of the first substrate. A first die is electrically coupled to a first set of contacts of the first contacts on the first side of the first substrate. The first die is configured to be coupled to a heat sink such that at least a portion of the heat sink is positioned vertically above at least a portion of the first die. The method also includes providing a second substrate having first contacts on a first side of the second substrate that is opposite to a second side of the second substrate that faces the first side of the first substrate. The first contacts of the second substrate are configured to be electrically coupled to a second die such that the second die is horizontally adjacent to the heat sink. The method further includes electrically coupling the first substrate and the second substrate to form a first package.

Another example provides a package that includes a first package. The first package includes a first substrate having first contacts on a first side of the first substrate, a first die electrically coupled to a first set of contacts of the first contacts on the first side of the first substrate, and a second substrate above and electrically coupled to the first substrate. The second substrate has first contacts on a first side of the second substrate that is opposite to a second side of the second substrate that faces the first side of the first substrate. The package also includes a heat sink and a second die. The heat sink is coupled to the first die such that at least a portion of the heat sink is positioned vertically above at least a portion of the first die. The second die is electrically coupled to the first contacts of the second substrate such that the second die is horizontally adjacent to the heat sink.

Another example provides a method of fabrication that includes providing a first package that includes a first substrate having first contacts on a first side of the first substrate, a first die electrically coupled to a first set of contacts of the first contacts on the first side of the first substrate, and a second substrate above and electrically coupled to the first substrate. The second substrate has first contacts on a first side of the second substrate that is opposite to a second side of the second substrate that faces the first side of the first substrate. The method also includes coupling a heat sink to the first die such that at least a portion of the heat sink is positioned vertically above at least a portion of the first die. The method further includes electrically coupling a second die to the first contacts of the second substrate such that the second die is horizontally adjacent to the heat sink.

### BRIEF DESCRIPTION OF THE DRAWINGS

Various features, nature and advantages may become apparent from the detailed description set forth below when taken in conjunction with the drawings in which like reference characters identify correspondingly throughout. It is noted that one or more figures are annotated with X-, Y-, and/or Z-axes to facilitate recognition of the orientation illustrated in each view.

FIG. 1 illustrates a cross-sectional profile view of an exemplary package compatible with a package assembly including components having an offset configuration.

FIG. 2 illustrates a cross-sectional profile view of an exemplary package compatible with a package assembly including components having an offset configuration.

FIG. 3 illustrates a cross-sectional profile view of an exemplary package compatible with a package assembly including components having an offset configuration.

FIG. 4 illustrates a cross-sectional profile view of an exemplary package compatible with a package assembly including components having an offset configuration.

FIG. 5 illustrates a cross-sectional profile view of an exemplary package compatible with a package assembly including components having an offset configuration.

FIG. 6 illustrates a cross-sectional profile view of an exemplary package compatible with a package assembly including components having an offset configuration.

FIG. 7 illustrates a cross-sectional profile view of an exemplary package compatible with a package assembly including components having an offset configuration.

FIG. 8 illustrates a cross-sectional profile view of an exemplary package compatible with a package assembly including components having an offset configuration.

FIG. 9 illustrates a cross-sectional profile view of an exemplary package compatible with a package assembly including components having an offset configuration.

FIG. 10 illustrates a cross-sectional profile view of an exemplary package compatible with a package assembly including components having an offset configuration.

FIG. 11 illustrates a cross-sectional profile view of an exemplary package compatible with a package assembly including components having an offset configuration.

FIG. 12 illustrates a top view of a substrate of a particular implementation of the exemplary package of FIG. 1.

FIG. 13 illustrates a top view of a substrate of a particular implementation of the exemplary package of FIG. 1.

FIG. 14 illustrates a top view of a substrate of a particular implementation of the exemplary package of FIG. 1.

FIG. 15 illustrates an exemplary sequence for fabricating an exemplary package compatible with a package assembly including components having an offset configuration.

FIG. 16 illustrates an exemplary sequence for fabricating an exemplary package compatible with a package assembly including components having an offset configuration.

FIG. 17 illustrates an exemplary sequence for fabricating an exemplary package compatible with a package assembly including components having an offset configuration.

FIG. 18 illustrates an exemplary sequence for fabricating an exemplary package compatible with a package assembly including components having an offset configuration.

FIG. 19 illustrates an exemplary sequence for fabricating an exemplary package compatible with a package assembly including components having an offset configuration.

FIG. 20 illustrates an exemplary sequence for fabricating an exemplary package compatible with a package assembly including components having an offset configuration.

FIG. 21 illustrates an exemplary flow diagram of a method of fabrication for a package compatible with a package assembly including components having an offset configuration.

FIG. 22 illustrates various electronic devices that may integrate an exemplary package compatible with a package assembly including components having an offset configuration as described herein.

FIG. 23 illustrates a block diagram of a particular electronic device that may integrate a package compatible with a package assembly including components having an offset configuration as described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnects are illustrated herein to highlight important features of the disclosure without unduly complicating the drawings.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

In some drawings, multiple instances of a particular type of feature are shown. In some circumstances, fewer than all of such features may be identified using a reference number. For example, a single reference number may be shown and associated with a representative instance of the feature so as not to obscure other aspects of the drawings.

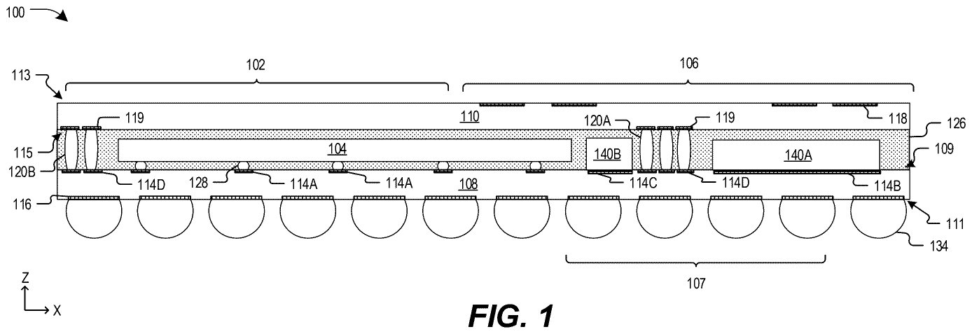

In some drawings in which multiple instances of a particular type of feature are used, different instances are distinguished by addition of a letter to the reference number. In this case, when the features as a group or a type are referred to herein (e.g., when no particular one of the features is being referenced), the reference number is used without a distinguishing letter. However, when one particular feature of multiple features of the same type is referred to herein, the reference number is used with the distinguishing letter. For example, referring to FIG. 1, multiple contacts are illustrated and associated with reference numbers 114A, 114B, 114C, and 114D. When referring to a particular one of these contacts, such as a contact 114A, the distinguishing letter “A” is used. However, when referring to any arbitrary one of these contacts or to these contacts as a group, the reference number 114 is used without a distinguishing letter.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

Improvements in manufacturing technology and demands for lower cost and more capable electronic devices have led to increasing complexity of integrated circuits (ICs). Often, more complex ICs have more complex interconnection schemes to enable interaction between ICs of a device. The number of interconnect layers for circuitry has substantially increased due to the large number of components (e.g., a die, an active component, a passive component, a device, a package, or the like) that are now interconnected in a state-of-the-art mobile application device.

These interconnections include back-end-of-line (BEOL) interconnect layers, which may refer to the conductive interconnect layers for electrically coupling to front-end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

State-of-the-art electronic devices (e.g., portable computing devices, mobile communication devices, wearable devices, special purpose computing devices, etc.) demand a small form factor, low cost, a tight power budget, and high electrical performance. Integrated circuit package design has evolved to meet these divergent goals. One approach to reducing package size is to integrate multiple dies (e.g., multiple semiconductor dies) within a single package. One example of a multi-die package is a two-dimensional (2D) package architecture, in which two or more dies are coupled to a package substrate side-by-side with one another. Dies in this configuration can interact with one another (e.g., via die-to-die interconnections) and with off-package components (e.g., via off-package interconnections). A challenge of such configurations is that die-to-die and off-package interconnections have different design criteria. For example, off-package interconnections are generally larger (e.g., in terms of line width, line spacing, etc.) than is needed for die-to-die interconnections. Various workarounds have been used to address this size difference. For example, additional devices (e.g., interposer devices or bridge die) can be added to a package to route die-to-die interconnections using smaller lines. As another example, additional layers or a separate stacked substrate can be added to the package substrate to provide die-to-die interconnection and redistribution routing to connect to off-package interconnections.

Another approach to reducing package size is a 2.5D package architecture, in which two or more devices are positioned side-by-side with one another on the package substrate, and one or more additional devices are stacked on at least one of the side-by-side devices. To illustrate, a stacked die arrangement can be coupled to a package substrate side-by-side with another die, a passive device, another die stack, etc. Stacked die schemes and chiplet architectures are becoming more common as significant power performance area (PPA) yield enhancements are demonstrated for stacked die and chiplet architecture product lines.

A three-dimensional (3D) package architecture includes a set of stacked and interconnected dies. Generally, a 3D package architecture can achieve higher performance, increased functionality, lower power consumption, and/or smaller footprint, as compared to providing the same circuitry in a monolithic die or in a 2D package architecture.

Aspects of the present disclosure are directed to a package compatible with a package assembly including components having an offset configuration. The package includes a first die and is configured to enable a second die to be stacked in a vertical direction above the bottom package. In some implementations, the second die is included in a second package, such as a top package of a package assembly, and is positioned such that a center of the second die or the second package is “offset” in a horizontal direction (e.g., along a lateral axis, a longitudinal axis, or both) with respect to a center of the package (e.g., a bottom package of the package assembly) or a center of the first die of the bottom package. The package can include a bottom substrate having the first die coupled to a surface of the bottom substrate, and a top substrate (e.g., such as an interposer), above and coupled to the bottom substrate. The top substrate includes a top surface that has first contacts configured to be coupled to the second die. The first contacts to be coupled to the second die are positioned (e.g., arranged) on the top substrate such that the second die is “offset” in a horizontal direction with respect to a center of the bottom package or a center of the first die of the package. In some implementations, the first contacts of the top substrate are arranged such that at least a portion of a footprint associated with the second die (or the second package) does not vertically overlap the first die, and at least a portion of the first die is not vertically overlapped by the footprint. The package configured to support an “offset configuration” (for “offset” positioning of the second die or the second package) may have a larger form factor—e.g., a horizontal area of the package having the offset configuration may be larger than a horizontal area of a bottom package of a conventional PoP. The larger form factor of the package (e.g., a bottom package of a package assembly) enables an additional component to be included side-by-side with the first die in the package. Additionally, or alternatively, the larger form factor and the configuration of the first contacts of the package (e.g., the bottom package) enables a component or a device, such as a heat sink, to be positioned above the portion of the first die of the package that is not vertically overlapped by a footprint associated with the second die or a footprint associated with the second package.

The disclosed package (e.g., which may be a bottom package of a package assembly) that includes the first contacts the define an offset position for the second die (or a second package) on the package, and/or in relation to the first die of the package, increases a horizontal area of the package as compared to a bottom package of a conventional PoP. In some aspects, the increased horizontal area that results from the configuration of the first contacts enables an additional component (that would otherwise not be included in the package) to be included side-by-side with the first die in the package and thereby shorten signal routing and improve performance between the first die and the additional component, increase a surface utilization of the bottom substrate of the package, or a combination thereof. Additionally, or alternatively, the first contacts define the footprint of the second die (and/or a second package) such that at least a portion of the first die is not vertically overlapped by the footprint. In some aspects, a region of the package that is above the nonoverlapped portion is thus available to be coupled to a heat dissipation component, such as a heat sink, which can improve thermal performance of the first die and/or the package without increasing a height of the package.

Some aspects of the present disclosure are directed to a package assembly, such as a PoP assembly, having an offset configuration. For example, the package assembly includes a first package (e.g., the bottom package) and a second package electrically coupled to first contacts on a top surface of a top substrate of the first package. The second package coupled to the first package is “offset” in a horizontal direction with respect to a center of the first package and/or a center of a first die of the first package. In some implementations, an additional component, such as a modem or a passive component, may be included side-by-side with the first die in the first package and below the second package. Additionally, or alternatively, at least a portion of the second package coupled to the first package does not vertically overlap the first die, and at least a portion of the first die is not vertically overlapped by the second package. The portion of the first die that is not vertically overlapped by the second package may be coupled to a component or a device, such as a heat sink, that is positioned above the portion of the first die and are horizontally adjacent to the second package.

The disclosed package assembly (having the offset configuration) provides one or more technical advantages and improvements. In some aspects, the disclosed package assembly provides improved electrical performance by having a component (e.g., that would otherwise not be included in first package) on the same substrate as the first die. To illustrate, having the component side-by-side with the first die in the first package shortens signal routing, improves performance between the first die and the component, and increases substrate surface utilization. Additionally, or alternatively, the disclosed package assembly provides improved thermal performance without increasing a height of the package assembly as compared to a conventional POP stack. To illustrate, a heat sink can be coupled to the first package above a portion of the first die such that the heat sink is horizontally adjacent to a second die (or the second package that includes the second die).

Exemplary Package Compatible with a Package Assembly Including Components Having an Offset Configuration

FIG. 1 illustrates a cross-sectional profile view of an exemplary package 100 compatible with a package assembly including components having an offset configuration. In FIG. 1, the package 100 includes a first substrate 108 coupled (e.g., electrically coupled) to a second substrate 110 by a set of interconnects 120 (e.g., one or more conductive interconnects). The second substrate 110 is positioned above (e.g., in a direction along the Z-axis) the first substrate 108. The first substrate 108 has a first side 109 and a second side 111. The second side 111 of the first substrate 108 is opposite of the first side 109 of the first substrate 108. The second substrate 110 has a first side 113 and a second side 115. The second side 115 of the second substrate 110 is opposite of the first side 113 of the second substrate 110. The second side 115 of the second substrate 110 faces the first side 109 of the first substrate 108.

Each of the substrates 108, 110 can include multiple metal layers separated by one or more dielectric layers. The metal layers of a respective substrate are interconnected with one another at various locations by vias to provide conductive paths through the thickness of the substrate. Additionally, the metal layers may be patterned to define contacts, conductive traces and optionally other features, such as coils of an inductor. In some examples, one or both of the substrates 108, 110 can be formed using lamination techniques and materials, or using redistribution layer (RDL) fabrication techniques and materials.

A substrate formed using the lamination techniques includes a metal-prepreg composite stack, in which the dielectric layers include fiber-reinforced polymer layers. A laminate substrate can be formed using conventional package substrate fabrication processes and materials. The dielectric layers can include or correspond to fiber reinforced polymer layers. To illustrate, each dielectric layer can be formed by application (e.g., lay up or lamination) of a pre-preg layer that includes fibers (e.g., strands, mats, tape, etc.) embedded within or coated with a polymer. Epoxy resins are a good choice for the polymer as many epoxies can be partially cured to facilitate handling and later fully cured in-place to facilitate crosslinking and adhesion between adjacent layers. The fibers provide beneficial mechanical characteristics, e.g., resistance to warpage, in a relatively thin substrate. The metal layers can include metal foil layers, often applied as full sheets and subsequently patterned using subtractive techniques (e.g., etching or other removal techniques). As a result, the metal layers tend to be relatively thick (as compared to deposited metal layers), to enable handling during full sheet placement. Additionally, the characteristic line width and line spacing (pitch) of lines of the metal layers is limited due to limitations of the subtractive techniques used to pattern the metal layers and clearances and dimensions that enable alignment of conductive vias between the metal layers.

A substrate formed using the RDL fabrication techniques includes a set of redistribution layers, in which the dielectric layers include unreinforced polymer layers. To illustrate, the material of each dielectric layer can be applied as a liquid or gel that is smoothed to form a substantially uniform layer using a spin-coating process or similar smoothing operation. Alternatively, the material of each dielectric layer can be applied as a dry film. In either case, the material includes a polymer (e.g., a polyimide) without fiber reinforcement in order to form a thin, uniform layer. In some cases, the polymer can subsequently be patterned using subtractive techniques, and the patterned polymer can be used (possibly in combination with a patterned photoresist layer) to guide formation of a metal layer. In such cases, the metal layers are formed using additive techniques, such as electroplating, chemical vapor deposition, physical vapor deposition, etc. Using such additive techniques enables formation of metal layers with finer lines than lines of the metal layers of a laminate substrate. In this context, “finer” lines refers to lines that have a smaller characteristic line width, a smaller characteristic pitch, a smaller characteristic line thickness, or a combination thereof, relative to a reference (e.g., lines formed according to the lamination techniques).

In some embodiments, a substrate can include a laminate portion and an RDL portion. For example, the substrate may include the RDL portion formed on the laminate portion. The laminate portion may provide mechanical support for the RDL portion as the dielectric layers of the RDL portion are thin and generally unreinforced, and the metal layers of the RDL portion are also thin.

In some embodiments, the second substrate 110 is or includes an interposer. An interposer can provide conductive connections to enable routing of signals between components on opposite sides of the interposer. The interposer may also provide mechanical/structural support. The interposer can include or be made of silicon, glass, or an organic material (e.g., epoxy or polyimide), as illustrative, non-limiting examples. In some implementations, the interposer includes a laminate or an RDL enabling routing of signals between different chips mounted on the interposer.

In some embodiments, the first substrate 108 includes a laminate substrate. Additionally, or alternatively, the first substrate 108 can include an RDL. In some such embodiments, the second substrate 110 includes a laminate substrate or an RDL. Alternatively, the second substrate 110 can include an RDL, an interposer, or a combination thereof. In some other embodiments, each of the first substrate 108 and the second substrate 110 includes a respective interposer.

The first substrate 108 includes first contacts 114 on the first side 109 of the first substrate 108 and includes second contacts 116 on the second side 111 of the first substrate 108. The first contacts 114 may be positioned on or define a portion of a first surface of the first substrate 108 on the first side 109 of the first substrate 108. Likewise, the second contacts 116 may be positioned on or define a portion of a second surface of the first substrate 108 on the second side 111 of the first substrate 108. The second substrate 110 includes contacts 118 (e.g., first contacts) on the first side 113 of the second substrate 110, and includes second contacts 119 on the second side 115 of the second substrate 110. The contacts 118 may be positioned on or define a portion of a first surface of the second substrate 110 on the first side 113 of the second substrate 110. Likewise, the second contacts 119 may be positioned on or define a portion of a second surface of the second substrate 110 on the second side 115 of the second substrate 110.

In some implementations, the first substrate 108, the second substrate 110, or both, includes a solder resist layer on a surface of the respective substrate and the solder resist layer includes openings exposing contacts of the substrate. For example, the first substrate 108 may include a solder resist layer on the second side 111 of the first substrate 108 and the solder resist layer may include openings exposing the second contacts 116 to enable balls 134 (e.g., solder balls) to be electrically coupled to the second contacts 116. To illustrate, the balls 134 may include or correspond to a ball grid array (BGA). In some aspects, the second contacts 116 are package contacts that enable the package 100 to be coupled to other off-package components, and the balls 134 are in contact with the second contacts 116. Although described as balls 134, in other implementations, the second contacts 116 enable another conductive interconnect, such as pillars, bumps (e.g., microbumps), a metal, etc.

The set of interconnects 120 is configured to electrically connect the first substrate 108 and the second substrate 110. For example, the set of interconnects 120 is electrically coupled to contacts 114D of the first substrate 108 and the second contacts 119 of the second substrate 110. In some implementations, the set of interconnects 120 includes multiple interconnects (e.g., multiple groups of interconnects), such as a first interconnect, a second interconnect, a third interconnect, or a combination thereof, as illustrative, non-limiting examples. The set of interconnects 120 can include copper clad balls, copper pillars, or other conductive features that extend between the substrates 108, 110 to enable (inter-) connections between one or more components electrically coupled to the first substrate 108 and one or more packages coupled to the second substrate 110, to enable connections between one or more components of the package 100 and one or more packages on top of the package 100, to enable provision of power to the one or more components of the package 100, or a combination thereof. As an illustrative example, the set of interconnects 120 enables the contacts 118 of second substrate 110 to be electrically coupled to the first substrate 108—e.g., to the contacts 114, 116 of the first substrate 108.

A first die 104 and one or more components 140 are electrically coupled to the first side 109 of the first substrate 108. For example, the first die 104 is electrically coupled to a first set of contacts 114A. To illustrate, the first die 104 may be coupled to the first set of contacts 114A by one or more contacts or interconnects 128. The one or more contacts or interconnects 128 can include, for example, microbumps, solder, solder paste, conductive pillars, or conductive pads (e.g., for pad-to-pad bonding). In some implementations, an underfill material is positioned between the first die 104 and the first substrate 108. In this example, also a first component 140A is electrically coupled to a second set of contacts 114B, and a second component 140B is electrically coupled to a third set of contacts 114C. Each of the first component 140A and the second component 140B may be coupled to the first substrate 108 by one or more contacts or interconnects, such as microbumps, solder, solder paste, conductive pillars, or conductive pads (e.g., for pad-to-pad bonding), as illustrative, non-limiting examples.

Each of the first die 104 and the first component 140A is an active component and includes integrated circuitry, such as a plurality of transistors and/or other circuit elements arranged and interconnected to form logic cells, memory cells, etc. Components of the integrated circuitry can be formed in and/or over a semiconductor substrate. Different implementations can use different types of transistors, such as a field effect transistor (FET), planar FET, finFET, a gate all around FET, or mixtures of transistor types. In some implementations, an FEOL process may be used to fabricate the integrated circuitry in and/or over the semiconductor substrate.

In some embodiments, one or more of the first die 104 or the first component 140A includes or corresponds to a microcontroller, an application specific integrated circuit (ASIC), a field programmable gate array (FPGA), a central processing unit (CPU) having one or more processing cores, an application processor, a processing system, or a system on chip (SoC). In the same or different embodiments, the first die 104 or the first component 140A includes or corresponds to a memory device, such as a static random-access memory (SRAM), a dynamic random-access memory (DRAM), flash memory, read-only memory (ROM), programmable read-only memory (PROM), erasable programmable read-only memory (EPROM), electrically erasable programmable read-only memory (EEPROM), a solid-state storage device (SSD), or a combination thereof. In the same or different embodiments, one or more of the first die 104 or the first component 140A includes or corresponds to another type of device, such as a power management integrated circuit (PMIC), a modem, a radio frequency (RF) device (e.g., one or more amplifiers), a light emitting diode (LED) integrated device, and/or a microelectromechanical (MEM) device (e.g., a surface acoustic wave (SAW) filter, a bulk acoustic wave (BAW) filter). Further, one or more of the first die 104 or the first component 140A can include any combination of the components listed above, and optionally various passive components (e.g., capacitors, inductors, resistors, or conductors) arranged and interconnected to form other circuit elements.

In some embodiments, the first die 104 or the first component 140A includes or corresponds to one or more semiconductor dies. For example, in some embodiments, each of the first die 104 and the first component 140A corresponds to a single semiconductor die. In other examples, one or more of the first die 104 or the first component 140A includes two or more semiconductor dies arranged in a stacked configuration. In such examples, the two or more semiconductor dies can include chiplets, where the term “chiplet” refers to an integrated circuit block, a functional circuit block, or other like circuit block specifically designed to work with one or more other chiplets to form a larger, more complex chiplet architecture. To illustrate, one or more of the first die 104 or the first component 140A can include two or more chiplets arranged and interconnected as a three-dimensional (3D) integrated device. In the same or different example, one or more of the first die 104 or the first component 140A includes one or more semiconductor dies and one or more additional components, such as an interposer, one or more passive components, etc. It is also noted that although a single first die 104 is shown, in other embodiments, the package 100 can include multiple first dies 104. Additionally, or alternatively, it is also noted that although a single component 140A is shown, in other embodiments, the package 100 can include multiple components 140A.

The second component 140B may include or correspond to a passive component). For example, the second component 140B (e.g., the passive component) can include, for example and without limitation, capacitive components, inductive components, or resistive components. To illustrate, the second component 140B (e.g., the passive component) that includes one or more capacitors can be electrically coupled to a power distribution network (PDN) of one of the first die 104 or the first component 140A to improve performance of the PDN. As another illustrative example, the second component 140B (e.g., the passive component) that includes one or more capacitors, one or more inductors, one or more resistors, or a combination thereof, can be electrically coupled to a radio frequency component to adjust impedance of one or more circuits. Although a single second component 140B (e.g., the passive component) is shown, in other embodiments, the package 100 can include multiple passive components, such as two or more passive components coupled to the first substrate 108.

An encapsulant 126 may occupy at least a portion of a space between the first substrate 108 and the second substrate 110. For example, the encapsulant 126 can at least partially encapsulate (e.g., surround) the first die 104, the set of interconnects 120, the one or more contacts or interconnects 128, the component 140, or a combination thereof. In some implementations, the encapsulant 126 includes or corresponds to a mold compound. Alternatively, the encapsulant 126 may be a different type of compound, such as adhesive or glue, that provides a mechanical connection between two or more of the first substrate 108, the second substrate 110, the first die 104, the set of interconnects 120, the one or more contacts or interconnects 128, or the component 140. The encapsulant 126 may be in contact with the first substrate 108, the second substrate 110, or both. For example, the encapsulant 126 may be in contact with the second side 115 of the second substrate 110, at least one of the second contacts 119, the first side 109 of the first substrate 108, at least one of the first contacts 114, or a combination thereof. In some implementations, the encapsulant 126 is optional and is omitted in some embodiments. Additionally, or alternatively, in some implementations the package 100 may include a thermal interface material on a top surface of the first die 104. For example, the thermal interface material may be positioned between (e.g., interposed between) the first die 104 and the second substrate 110 and may be selected to improve heat transfer (e.g., heat conduction) from the first die 104 toward the second substrate 110.

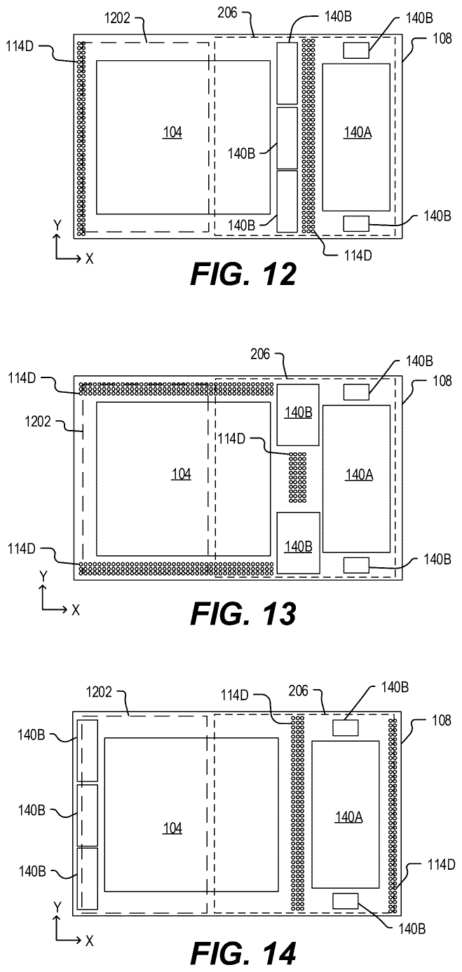

As shown in FIG. 1, the set of interconnects 120 includes first interconnects 120A and second interconnects 120B. The first interconnects 120A are positioned between the first component 140A and the second component 140B, and the first die 104 is positioned between the first interconnects 120A and the second interconnects 120B. It is noted that positioning of the set of interconnects 120, the first die 104, and the component 140 is based on a layout of the contacts 114 on the first side 109 of the first substrate 108. Examples of a top view of the first substrate 108 illustrating different layouts are described further herein at least with reference to FIGS. 12-14.

In some implementations, a first portion 102 of the second substrate 110 is configured to be coupled (e.g., thermally coupled) to a heat sink (e.g., one or more heat sinks). For example, the heat sink coupled (e.g., mechanically coupled) to the second substrate 110 may be thermally coupled to the first die 104. In some implementations, the first portion 102 of the second substrate 110 includes a region of a surface of the second substrate 110 and/or a plurality of through-substrate vias configured to enable heat to be transferred from the second side 115 of the second substrate 110 to the first side 113 of the second substrate 110.

The heat sink may be a unitary (e.g., monolithic) mass of metal (e.g., copper, aluminum, or another metal or alloy). It is noted that the heat sink may also be referred to as a heat slug. Additionally, or alternatively, the heat sink has an upper surface that includes fins, pins, or other features configured to increase a surface area available for heat exchange. The heat sink is configured to be coupled to the first portion 102 such that at least a part of the heat sink vertically (e.g., a vertical direction is along the Z-axis) overlaps at least a part of the first die 104. In some embodiments, the heat sink is vertically offset from the first die 104.

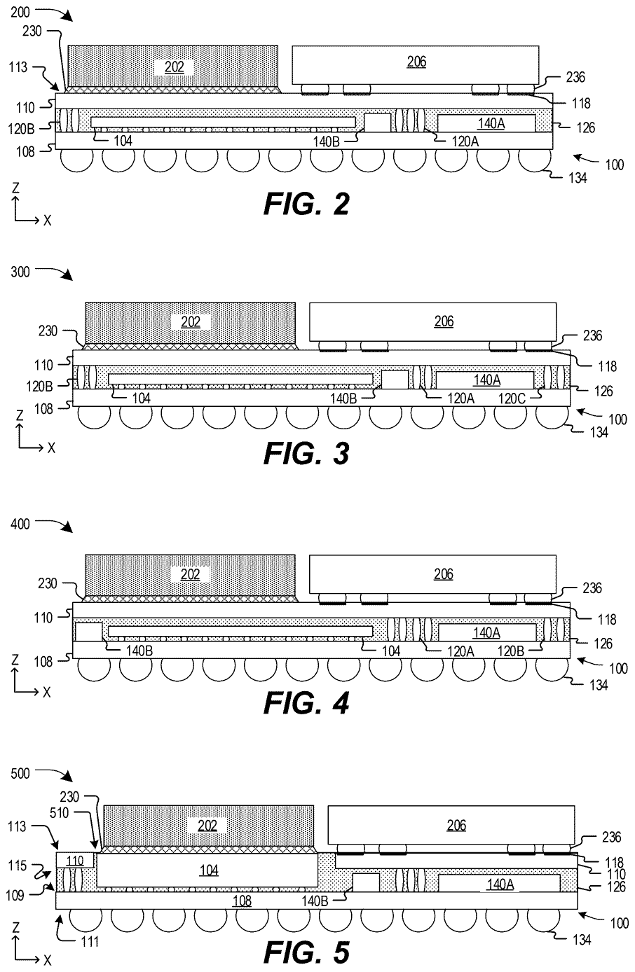

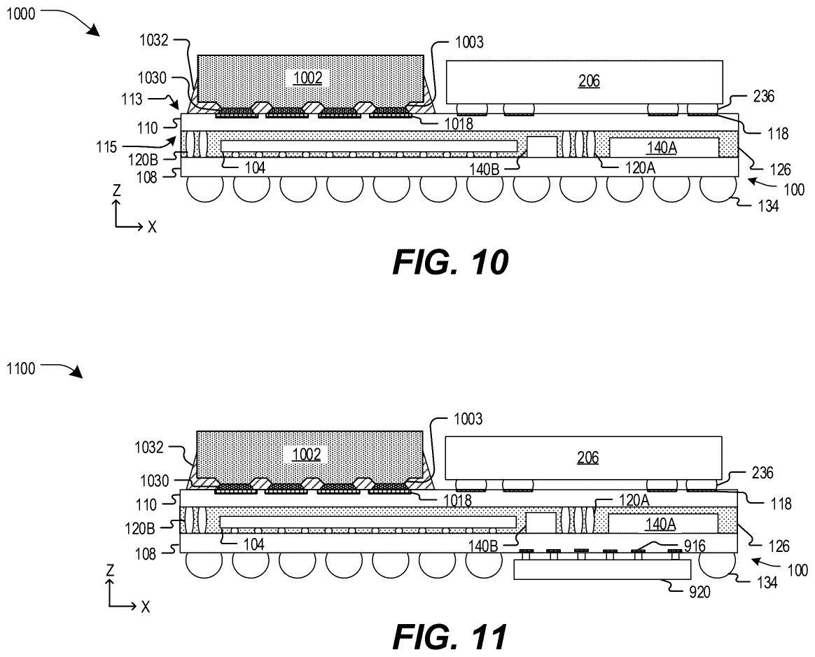

In some implementations, the heat sink is coupled to the first portion 102 by an adhesive material. An example of the heat sink coupled to the second substrate 110 by an adhesive material is described further herein at least with reference to FIG. 2-4 or 9. In other implementations, the first portion 102 includes contacts on the first side 113 of the second substrate 110 and the heat sink is coupled to the contacts. For example, the heat sink may define protrusions that are configured to be coupled to the contacts of the second substrate 110. An example of the heat sink that defines protrusions is described further herein at least with reference to FIG. 10 or 11. In some other implementations, the first portion 102 of the second substrate 110 is omitted (e.g., the second substrate 110 includes an opening that defines a through channel or does not extend over a portion or an entirety of the first die 104). In some such implementations, the heat sink may be coupled to first die 104. For example, the heat sink may be coupled to the first die 104 by an adhesive material that is in contact with a top surface of the first die 104. An example of the heat sink coupled to the first die 104 by an adhesive material is described further herein with reference to FIGS. 5-8.

In some implementations, a second portion 106 (a region of a surface) of the second substrate 110 is associated with a second die to be coupled (e.g., electrically coupled) to the second substrate 110. For example, the contacts 118 configured to be coupled to the second die are positioned (e.g., arranged) on the second substrate 110 such that the second die, when coupled to the package 100, is “offset” in a horizontal direction with respect to a center of the package 100 or a center of the first die 104. The second portion 106 that includes the contacts 118 (e.g., contacts to be electrically coupled to the second die) may be associated with or correspond to a footprint of the second die. The one or more contacts 118 may include microbumps, solder, solder paste, conductive pillars, or conductive pads (e.g., for pad-to-pad bonding). To illustrate, the contacts 118 on the first side 113 of the second substrate 110 can be package contacts that are configured to be electrically coupled to a BGA of the second die. An example of the second die coupled to the second substrate 110 is described further herein at least with reference to FIGS. 2-11. The second die may include a die, an integrated circuit, a passive component, another electrical component, or a combination thereof, as illustrative, non-limiting examples. In some implementations, the second die is included in a second package that is configured to be coupled to the contacts 118.

In some implementations, a portion 107 (e.g., a region of a surface) of the first substrate 108 may optionally be configured to be coupled to a component, such as a die, an integrated circuit, a device, a passive component, a package, etc. For example, the component may be electrically coupled (e.g., via one or more contacts or interconnects) to the portion 107 of the first substrate 108. The one or more contacts or interconnects may include microbumps, solder, solder paste, conductive pillars, or conductive pads (e.g., for pad-to-pad bonding). In some implementations, the component coupled to the portion 107 of the first substrate 108 includes a PMIC. As an example, a PMIC coupled to the portion 107 of the first substrate 108 is described further herein at least with reference to FIG. 9 or 11.

In some implementations, the first die 104 includes a processor (e.g., an application processor), the first component 140A includes a controller or a modem, the second component 140B includes a passive device, and the contacts 118 are configured to be coupled to the second die (and/or a second package that includes the second die) that includes a memory (e.g., a DRAM). Additionally, or alternatively, in some implementations, the package 100 is coupled to a frame, such as a middle frame structure. The frame may include or be formed from aluminum, an aluminum alloy, stainless steel, or titanium, as illustrative, non-limiting examples. For example, the frame may be configured to support and/or be coupled to a housing, a cover, a heat spreader (e.g., a graphite heat spreader), a display screen, a panel or plate, a battery, or a combination thereof, as described further herein at least with reference to FIG. 23. In some implementations, the package 100 coupled to the frame is included in or part of an electronic device, such as a portable communication device (e.g., a mobile phone) or a tablet. Additionally, or alternatively, the package 100 may be integrated within a mobile device, a hand-held personal communication system (PCS) unit, a portable data unit, a global positioning system (GPS) enabled device, a navigation device, a set top box, a music player, a video player, an entertainment unit, a virtual reality (VR) device, an augmented reality (AR) device, an extended reality (XR) device, a fixed location data unit, a communications device, a smartphone, a tablet computer, a computer, a wearable device, an Internet of things (IoT) device, a data center component, a server, a router, a vehicle, a mobile location data unit, a mobile phone, a cellular phone, a session initiation protocol (SiP) phone, a phablet, a portable computer, a mobile computing device, a wearable computing device, a personal digital assistant (PDA), a monitor, a computer monitor, a television, a tuner, a radio, a satellite radio, a digital music player, a portable music player, a digital video player, a digital video disc (DVD) player, a portable digital video player, an automobile, a vehicle component, avionics systems, a drone, a multicopter, or a combination thereof.

It should be understood that the package 100 may include additional components, other components, fewer components, or a combination thereof, to support the functionality described herein. As non-limiting examples, the package 100 may include additional ICs, additional layers, additional dies, additional packages, additional interconnects, additional structures, other components, different components, or a combination thereof, to support the functionality and technical advantages disclosed herein.

The package 100 is compatible with a package assembly including components having an offset configuration by having the contacts 118 that enable the second die to be coupled to the second portion 106 at an offset in a horizontal direction (e.g., in a direction along the X-axis) with respect to the position of the first die 104 in the package 100. A technical advantage of the package 100 having the contacts 118 configured to be coupled to the second die (and/or a second package that includes the second die) includes increased horizontal area of the package 100 (e.g., the first substrate 108) that enables an additional component 140 (e.g., that would otherwise not be included in the package 100) to be included side-by-side with the first die 104 in the package 100 and thereby shorten signal routing and improve performance between the first die 104 and the additional component 140, increase a surface utilization of the first substrate 108, or a combination thereof. Additionally, or alternatively, another technical advantage of the package 100 having the contacts 118 configured to be coupled to a second device is that a region (e.g., the first portion 102) of the package 100 that is above a portion of the first die 104 that is not be vertically overlapped by the footprint (associated with the second die) is available to be coupled to a heat dissipation component, such as a heat sink. The availability of the first portion 102 to be coupled to the heat dissipation component may increase a surface utilization of the package 100.

In a particular implementation, the package 100 includes a first substrate (e.g., the first substrate 108) having first contacts (e.g., the contacts 114) on a first side (e.g., the first side 109) of the first substrate. The package 100 also includes a first die (e.g., the first die 104) electrically coupled to a first set of contacts (e.g., the first set of contacts 114A) of the first contacts on the first side of the first substrate. The first die is configured to be coupled to a heat sink such that at least a portion of the heat sink is positioned vertically above at least a portion of the first die. The package 100 further includes a second substrate (e.g., the second substrate 110) above and electrically coupled to the first substrate. The second substrate having first contacts (e.g., the contacts 118) on a first side (e.g., the first side 113) of the second substrate (e.g., the second substrate 110) that is opposite to a second side (e.g., the second side 115) of the second substrate (e.g., the second substrate 110) that faces the first side of the first substrate. The first contacts of the second substrate are configured to be electrically coupled to a second die such that the second die is horizontally adjacent to the heat sink—e.g., horizontally adjacent to the heat sink such that a horizontal plane passes through each of the second die and the heat sink, and the second die and the heat sink are neighboring components or have one or more components interposed between the second die and the heat sink.

FIGS. 2-11 illustrate cross-sectional profile views of exemplary packages, such as package assemblies including components having an offset configuration. The packages of FIGS. 2-11 include many of the same components and features as are described above with reference to FIG. 1. Such components and features are physically and operationally the same as described above with reference to FIG. 1 and are labeled in FIGS. 2-11 using the same reference numbers. In some implementations, the packages of FIGS. 2-11 include all of the same features and components as the package 100 of FIG. 1; however, some components and features illustrated in FIG. 1 have been omitted from (or are not labeled with reference numbers in) FIGS. 2-11 for simplicity of illustration and to highlight differences between the package 100 and the respective packages of FIGS. 2-11. Omission of such features and reference numbers should not be understood as limiting the features and components of FIGS. 2-11 to only those specifically called out below. For example, while FIGS. 2-11 do not show the second contacts 116 of FIG. 1, each of the packages of FIGS. 2-11 can include the second contacts 116.

FIG. 2 illustrates a cross-sectional profile view of a package 200 compatible with a package assembly including components having an offset configuration. In some aspects, the package 200 includes the package 100 of FIG. 1. The package 200 includes a heat sink 202 and a second die 206 coupled to the second substrate 110. The second die 206 may include a device, an integrated circuit, a passive component, another electrical component, or a combination thereof, as illustrative, non-limiting examples. In some implementations, the second die 206 is included in a second package, such as a second package that is coupled to the contacts 118 of the package 100.

The heat sink 202 may be a unitary (e.g., monolithic) mass of metal (e.g., copper, aluminum, or another metal or alloy). The heat sink 202 is configured to receive heat from a heat source, such as the first die 104, and dissipate the heat. Additionally, or alternatively, the heat sink 202 has an upper surface that includes fins, pins, or other features configured to increase a surface area available for heat exchange.

The heat sink 202 is coupled to the second substrate 110 by an adhesive material 230. For example, the adhesive material 230 is in contact with the heat sink 202 and the second substrate 110. To illustrate, the heat sink 202 is coupled to the first portion 102 of the second substrate 110 as described above with reference to the package 100 of FIG. 1. For example, the heat sink 202 is configured to be coupled to the first portion 102 such that at least a part of the heat sink vertically overlaps at least a part of the first die 104.

The adhesive material 230 is positioned between the heat sink 202 and the first die 104 and the first die 104 is positioned between the heat sink 202 and the first substrate 108. The heat sink 202 coupled to the second substrate 110 is thermally coupled to the first die 104. In some implementations, the second substrate 110 also includes a plurality of through-substrate vias positioned between the heat sink 202 and the first die 104. For example, the through-substrate vias may extend from the first side 113 to the second side 115 of the second substrate 110. The through-substrate vias are configured to facilitate transfer of heat generated by the first die 104 to the heat sink 202.

The second die 206 is coupled to the first side 113 of the second substrate 110. For example, the second die 206 may be coupled (e.g., electrically coupled) to the contacts 118 on the first side 113 of the second substrate 110. In some implementations, the second die 206 is coupled to the contacts 118 by solder 236 or solder paste. In some other implementations, the second die 206 may be electrically coupled to the contacts 118 by microbumps, conductive pillars, solder, solder paste, conductive pads (e.g., for pad-to-pad bonding), or other similar electrical interconnects. Additionally, or alternatively, the second die 206 is included in a package that is coupled to the package 100. For example, the package that includes the second die 206 can be coupled to the contacts 118 of the package 100.

The second die 206 and the heat sink 202 are horizontally adjacent to each other, such that a horizonal plane passes through the second die 206 and the heat sink 202. In some implementations, one or more other components are included in the package and are horizontally adjacent to the second die 206 and the heat sink 202. For example, at least one of the one or more other components may be horizontally adjacent to the second die 206 and the heat sink 202, and positioned between (e.g., interposed between) the second die 206 and the heat sink 202 Accordingly, the second die 206 and the heat sink 202 that are horizontally adjacent may be neighboring components or may be separated by one or more intervening components. It is noted that in implementations in which the second die 206 is included in a second package, the heat sink 202 may be horizontally adjacent to the second package. In some such implementations, depending on a position of the second die 206 within the second package, a horizontal plane that passes through the second package and the heat sink 202 may not necessarily pass through the second die 206.

The second die 206 may include integrated circuitry, such as a plurality of transistors and/or other circuit elements arranged and interconnected to form logic cells, memory cells, etc. Components of the integrated circuitry can be formed in and/or over a semiconductor substrate. Different implementations can use different types of transistors, such as an FET, a planar FET, a finFET, a gate all around FET, or mixtures of transistor types. In some implementations, an FEOL process may be used to fabricate the integrated circuitry in and/or over the semiconductor substrate.

In some embodiments, the second die 206 includes or corresponds to a microcontroller, an ASIC, an FPGA, a CPU having one or more processing cores, an application processor, a processing system, or an SoC. In the same or different embodiments, the second die 206 includes or corresponds to a memory device, such as an SRAM, a DRAM, flash memory, ROM, PROM, EPROM, EEPROM, an SSD, or a combination thereof. In the same or different embodiments, the second die 206 includes or corresponds to another type of device, such as a PMIC, a modem, an RF device (e.g., one or more amplifiers), an LED integrated device, and/or an MEM device (e.g., an SAW filter, a BAW filter), as illustrative, non-limiting examples. Further, the second die 206 can include any combination of the components listed above, and optionally various passive components (e.g., capacitors, inductors, resistors, or conductors) arranged and interconnected to form other circuit elements. In some embodiments, the second die 206 is a passive component.

In some embodiments, the second die 206 includes or corresponds to one or more semiconductor dies. For example, in some embodiments, the second die 206 corresponds to a single semiconductor die. In other examples, the second die 206 includes two or more semiconductor dies arranged in a stacked configuration.

In the package 200 illustrated in FIG. 2, the first die 104 may be a processor (having logic circuitry) and the second die 206 may include a memory. Additionally, or alternatively, the first component 140A may include a PMIC, a modem, or a controller, and the second component 140B may include a passive component. The first die 104 and the second die 206 are arranged to support an offset configuration, such as an offset configuration in which the first die 104 and the second die 206 are horizontally offset with respect to each other. In the offset configuration, the first die 104 is offset (in a horizontal direction along the X-axis) with respect to the second die 206 such that an entirety of the first die 104 does not overlap with the second die 206 in a vertical direction (e.g., along the Z-axis) and an entirety of the second die 206 does not overlap with the first die 104 in the vertical direction. A technical advantage of the package 200 includes improved electrical performance by having the component 140 on the same substrate as the first die 104, improved thermal performance as compared to a conventional package assembly, increased substrate surface utilization, or a combination thereof. Additionally, or alternatively, another technical advantage of the package 200 includes improved thermal performance without increasing a height of the package 200 as compared to a conventional package assembly (e.g., a PoP). To illustrate, the heat sink 202 is coupled to the package 100 above a portion of the first die 104 such that the heat sink 202 is horizontally adjacent to the second die 206.

In the package 200 illustrated in FIG. 2, the set of interconnects 120 includes the first interconnects 120A and the second interconnects 120B. The first interconnects 120A are positioned between the first die 104 and the first component 140A. The first die 104 is positioned between the first interconnects 120A and the second interconnects 120B.

During operation of the package 200, the first die 104 produces heat and the heat sink 202 is configured to facilitate removal of heat from the first die 104. For example, integrated circuit components of the first die 104 can generate heat as a result of normal operation. To illustrate, if the first die 104 includes one or more processing cores, heat generated during processing operations can increase the temperature in some local regions of the first die 104 above a threshold temperature at which operation of the first die 104 is throttled to avoid damaging the first die 104 (e.g., due to thermal stresses, electromigration, etc.). The heat sink 202 is thermally coupled to the first die 104 to provide a relatively large thermal mass to extract heat from the first die 104. In some embodiments, an upper surface of the heat sink 202 can be thermally coupled to one or more additional heat mitigation devices (e.g., a heat exchanger or heat spreader) to remove heat from the heat sink 202. Additionally, or alternatively, the heat sink 202 can include features to facilitate removal of the heat, such as fins, pins, or other features that improve heat removal from the heat sink 202 at or near an upper surface of the heat sink 202.

In a particular implementation, a package (e.g., the package 100) includes a first substrate (e.g., the first substrate 108) having first contacts (e.g., the contacts 114) on a first side (e.g., the first side 109) of the first substrate. The package 100 also includes a first die (e.g., the first die 104) electrically coupled to a first set of contacts (e.g., the first set of contacts 114A) of the first contacts on the first side of the first substrate and configured to be coupled to a heat sink (e.g., the heat sink 202) such that at least a portion of the heat sink is positioned vertically above at least a portion of the first die. The package 100 further includes a second substrate (e.g., the second substrate 110) above and electrically coupled to the first substrate. The second substrate having first contacts (e.g., the contacts 118) on a first side (e.g., the first side 113) of the second substrate (e.g., the second substrate 110) that is opposite to a second side (e.g., the second side 115) of the second substrate (e.g., the second substrate 110) that faces the first side of the first substrate. The first contacts of the second substrate are configured to be electrically coupled to a second die (e.g., the second die 206) such that the second die is horizontally adjacent to the heat sink.

In a particular implementation, a package (e.g., the package 200) includes a first package (e.g., the package 100). The first package includes a first substrate (e.g., the first substrate 108) having first contacts (e.g., the contacts 114) on a first side (e.g., the first side 109) of the first substrate, a first die (e.g., the first die 104) electrically coupled to a first set of contacts (e.g., the first set of contacts 114A) of the first contacts on the first side of the first substrate, and a second substrate (e.g., the second substrate 110) above and electrically coupled to the first substrate. The second substrate has first contacts (e.g., the contacts 118) on a first side (e.g., the first side 113) of the second substrate that is opposite to a second side (e.g., the second side 115) of the second substrate that faces the first side of the first substrate. The package also includes a heat sink (e.g., the heat sink 202) and a second package (e.g., including the second die 206). The heat sink is coupled to the first die such that at least a portion of the heat sink is positioned vertically above at least a portion of the first die. The second die is electrically coupled to the first contacts of the second substrate such that the second die is horizontally adjacent to the heat sink.

FIG. 3 illustrates a cross-sectional profile view of a package 300 compatible with a package assembly including components having an offset configuration. The package 300 includes or corresponds to the package 200. The set of interconnects of the package 300 includes the first interconnects 120A, the second interconnects 120B, and third interconnects 120C. The first interconnects 120A are positioned between the first die 104 and the first component 140A. The first die 104 is positioned between the first interconnects 120A and the second interconnects 120B. The first component 140A is positioned between the first interconnects 120A and the third interconnects 120C. A technical advantage of the package 300 includes improved substrate surface utilization and improved electrical performance by enabling components (e.g., the first die 104 and the component 140) and interconnects 120 to be positioned to provide efficient routing.

FIG. 4 illustrates a cross-sectional profile view of a package 400 compatible with a package assembly including components having an offset configuration. The package 400 includes or corresponds to the package 200. The set of interconnects 120 include the first interconnects 120A and the second interconnects 120B positioned such that the first component 140A is positioned in between the first interconnects 120A and the second interconnects 120B. Additionally, as compared to the package 200, the second component 140B of the package 400 is coupled to the first substrate 108 at a different location. For example, the first die 104 is positioned between the second component 140B and the first interconnects 120A. A technical advantage of the package 400 includes improved substrate surface utilization and improved electrical performance by having components (e.g., the first die 104 and the component 140) and interconnects 120 positioned to provide efficient routing.

FIG. 5 illustrates a cross-sectional profile view of a package 500 compatible with a package assembly including components having an offset configuration. The package 500 includes or corresponds to the package 200. The second substrate 110 includes a through channel 510 between the first side 113 of the second substrate 110 and the second side 115 of the second substrate 110. To illustrate, the through channel 510 may extend from a first opening on the first side 113 of the second substrate 110 to a second opening on the second side 115 of the second substrate 110. Accordingly, as a result of the first opening on the first side 113 of the second substrate 110, the first side 109 of the first substrate 108 has a first surface area that is greater than a second surface area of the first side 113 of the second substrate 110. Additionally, because of the through channel 510, the adhesive material 230 is in contact with the first die 104, the encapsulant 126, or a combination thereof. As compared to the package 200, the heat sink 202 may provide increased heat removal from the first die 104. Additionally, the second substrate 110 of the package 500 may be more resistant to warpage as a result of heat as compared to the package 200 of FIG. 2. A technical advantage of the package 500 includes a compact design, improved resistance to substrate warpage, and improved heat dissipation by positioning the heat sink 202 on the first die 104.

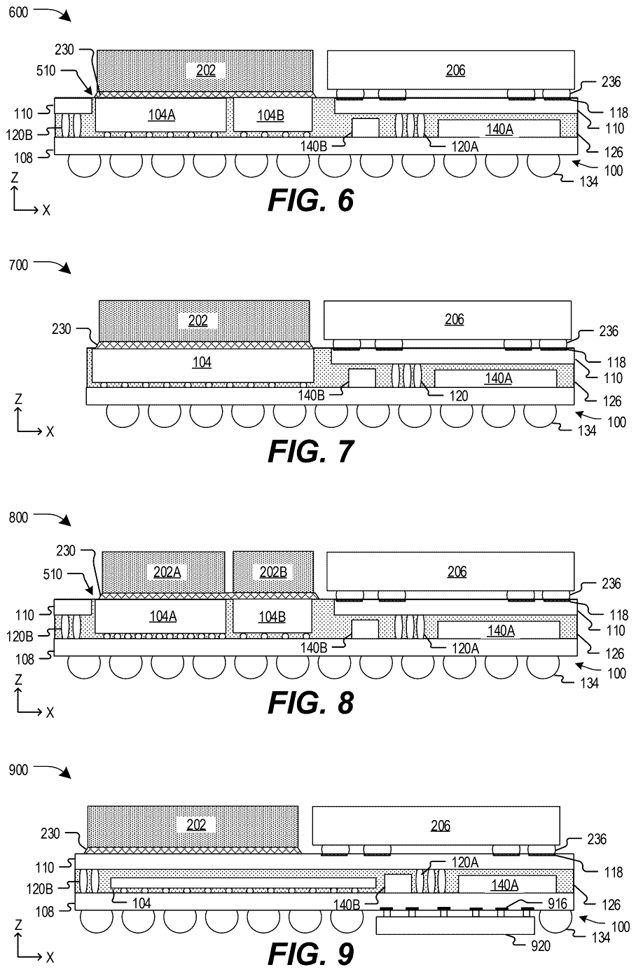

FIG. 6 illustrates a cross-sectional profile view of a package 600 compatible with a package assembly including components having an offset configuration. The package 600 includes or corresponds to the package 500. The package 600 includes multiple first dies 104, such as a die 104A and a die 104B. The adhesive material 230 is coupled to (e.g., in contact with) the die 104A and the die 104B, and the encapsulant 126. A technical advantage of the package 600 includes a compact design, improved resistance to substrate warpage, and improved heat dissipation by positioning the heat sink 202 on the first die 104.

FIG. 7 illustrates a cross-sectional profile view of a package 700 compatible with a package assembly including components having an offset configuration. The package 700 includes or corresponds to the package 500. As compared to the package 500, the second substrate 110 of the package 700 does not include the through channel 510; rather, the second substrate 110 of the package 700 does not extend horizontally (e.g., along the X-axis) past the first die 104. Accordingly, the first side 109 of the first substrate 108 has a first surface area that is greater than a second surface area of the first side 113 of the second substrate 110. Similar to the package 500, the package 700 may be more resistant to warpage as a result of heat as compared to the package 200 of FIG. 2. Additionally, as compared to the package 500, the package 700 does not include one or more interconnects, such as the second interconnects 120B, of the set of interconnects 120. A technical advantage of the package 700 includes a compact design, improved resistance to substrate warpage, and improved heat dissipation by positioning the heat sink 202 on the first die 104.

FIG. 8 illustrates a cross-sectional profile view of a package 800 compatible with a package assembly including components having an offset configuration. The package 800 includes or corresponds to the package 600. The package 800 includes multiple heat sinks 202, such as a first heat sink 202A and a second heat sink 202B. It is noted that although the second substrate 110 is shown as having a single through channel 510, in other implementations, the second substrate 110 may include multiple through channels, such as a first through channel associated with the die 104A and the first heat sink 202A, and a second through channel associated with the die 104B and the second heat sink 202B. Additionally, or alternatively, the second substrate 110 may have a through channel 510 for the die 104B and the second heat sink 202B, and the second substrate 110 may not extend horizontally past the die 104A and the first heat sink 202A. A technical advantage of the package 800 includes a compact design, improved resistance to substrate warpage, and improved heat dissipation by positioning the heat sink 202 on the first die 104.

FIG. 9 illustrates a cross-sectional profile view of a package 900 compatible with a package assembly including components having an offset configuration. The package 900 includes or corresponds to the package 200. The package 900 includes a PMIC 920 coupled to the second side 111 of the first substrate 108. For example, the PMIC 920 may be coupled to the portion 107 of the first substrate 108. To illustrate, the first substrate 108 may include a set of contacts 916 on the second side 111 of the first substrate 108. The set of contacts 916 may be configured to enable the PMIC 920 to be coupled to the first substrate 108. The PMIC 920 may be coupled (e.g., electrically coupled) to the set of contacts 916 by microbumps, solder, solder paste, conductive pillars, or conductive pads (e.g., for pad-to-pad bonding), as illustrative, non-limiting examples. Although the second side 111 of the first substrate 108 is described as being coupled to the PMIC 920, the PMIC 920 may optionally be replaced with another device, such as a die, a microcontroller, an ASIC, an FPGA, a CPU, a memory device, a modem, an RF device (e.g., one or more amplifiers), an LED integrated device, and/or an MEM device (e.g., an SAW filter, a BAW filter), or a passive device, as illustrative, non-limiting examples. A technical advantage of the package 900 includes a compact design, improved substrate surface utilization, and improved electrical performance by coupling the PMIC 920 to the first substrate 108.

FIG. 10 illustrates a cross-sectional profile view of a package 1000 compatible with a package assembly including components having an offset configuration. The package 1000 includes or corresponds to the package 200. The second substrate 110 of the package 100 includes contacts 1018 (on the first portion 102) on the first side 113 of the second substrate 110. The contacts 1018 are configured to be coupled to a heat sink 1002. The heat sink 1002 may include or correspond to the heat sink 202 of FIG. 2. The heat sink 1002 is configured to be coupled to the first portion 102 such that at least a part of the heat sink vertically overlaps at least a part of the first die 104.

The heat sink 1002 defines protrusions 1003 that are configured to be thermally coupled, via at least the contacts 1018, to the first die 104. For example, the heat sink 1002 may be coupled to the contacts 1018 by an interconnect 1030, such as microbumps, conductive pillars, solder, solder paste, conductive pads (e.g., for pad-to-pad bonding), or other similar electrical interconnects. Although the heat sink 1002 is described as including the protrusion 1003, in other implementations, the heat sink 1002 may not include the protrusions 1003.

In some implementations, the second substrate 110 also includes a plurality of through-substrate vias positioned between the heat sink 1002 and the first die 104. The through-substrate vias are configured to facilitate transfer of heat generated by the first die 104 to the heat sink 1002.

In a particular aspect, the heat sink 1002 is a unitary (e.g., monolithic) mass of metal (e.g., copper, aluminum, or another metal or alloy). For example, the heat sink 1002 can be machined from a solid block of metal to define the protrusions 1003 (e.g., using a milling technique, selective etching, or another subtractive process). Alternatively, the heat sink 1002 with the protrusions 1003 can be formed using an additive process, such as casting, laser sintering, selective melting, etc.

The protrusions 1003 are spaced apart from one another at a distance selected to (e.g. configured to) facilitate even distribution of an underfill material 1032. For example, the underfill material 1032 can be disposed between the heat sink 1002 and the second substrate 110 in a region between two or more of the protrusions 1003. Additionally, the underfill material 1032 may at least partially encapsulate the heat sink 1002.

A technical advantage of configuring the heat sink 1002 with the protrusions 1003 is that the protrusions 1003 facilitate use of conventional surface mount techniques to couple the heat sink 1002 to the second substrate 110 of the package 1000. A further technical advantage of configuring the heat sink 1002 with the protrusions 1003 is that one or more of the protrusions 1003 can be electrically coupled, via solder (e.g., the interconnect 1030), to one of the contacts 1018 that is coupled to a ground of the second substrate 110. In this arrangement, the heat sink 1002 can also provide electromagnetic shielding for components of the package 1000. A technical advantage of the package 600 includes improved heat dissipation by coupling the heat sink 1002 on the second substrate 110 above the first die 104.

An additional technical advantage of configuring the heat sink 1002 with the protrusions 1003 is that the protrusions 1003 enable the heat sink 1002 to stand off from the second substrate 110 similar to a conventional flip chip or surface mount component which can improve warpage characteristics of the package 1000 as compared to, for example, use of a heat sink that includes a flat bottom surface rather than the protrusions 1003. For example, a flat-bottomed heat sink could be coupled to the second substrate 110 using a thermal interface material or adhesive. In this arrangement, stresses on the second substrate 110 due to interaction with the flat-bottomed heat sink can be very different from stresses on the second substrate 110 due to thermal interaction between the heat sink 1002 and at least the first die 104. This uneven distribution of stresses can increase the risk of warpage. In contrast, by configuring the heat sink 1002 with the protrusions 1003, the stresses on the second substrate 110 can be reduced and thereby reduce the risk of warpage.

FIG. 11 illustrates a cross-sectional profile view of a package 1100 compatible with a package assembly including components having an offset configuration. The package 1100 includes or corresponds to the package 1000. The package 1100 includes a PMIC 920 coupled to the second side 111 of the first substrate 108. For example, the PMIC 920 may be coupled to the portion 107 of the first substrate 108. To illustrate, the first substrate 108 may include a set of contacts 916 on the second side 111 of the first substrate 108. The set of contacts 916 may be configured to enable the PMIC 920 to be coupled to the first substrate 108. The PMIC 920 may be coupled (e.g., electrically coupled) to the set of contacts 916 by microbumps, solder, solder paste, conductive pillars, or conductive pads (e.g., for pad-to-pad bonding), as illustrative, non-limiting examples. Although the second side 111 of the first substrate 108 of the package 1100 is described as being coupled to the PMIC 920, the PMIC 920 may optionally be replaced with another device, such as a die, a microcontroller, an ASIC, an FPGA, a CPU, a memory device, a modem, an RF device (e.g., one or more amplifiers), an LED integrated device, and/or an MEM device (e.g., an SAW filter, a BAW filter), or a passive device, as illustrative, non-limiting examples. A technical advantage of the package 1100 includes improved heat dissipation coupling the heat sink 1002 on the second substrate 110 above the first die 104, and includes a compact design, improved substrate surface utilization, and improved electrical performance by coupling the PMIC 920 to the first substrate 108.

While FIGS. 1-11 illustrate example packages, it is noted that the package of any of FIGS. 1-11 can be integrated with or included within a wide variety of other devices. For example, any of the packages of FIGS. 1-11 can include or be coupled to one or more components, such as a PMIC, an application processor, a modem, a radio frequency (RF) device, a passive device, a filter, a capacitor, an inductor, a transmitter, a receiver, a gallium arsenide (GaAs) based integrated device, a surface acoustic wave (SAW) filter, a bulk acoustic wave (BAW) filter, a silicon (Si) based integrated device, a silicon carbide (SiC) based integrated device, a memory, power management processor, and/or combinations thereof. In such implementations, the package of FIGS. 1-11 can operate as any of these components (or a combination of these components) that includes active circuitry.

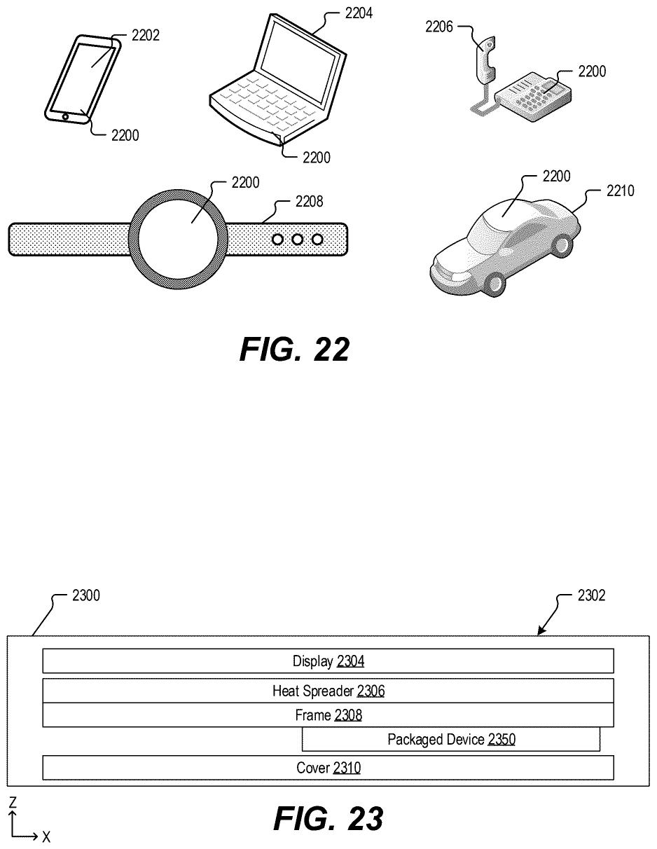

In some implementations, any of the packages of FIGS. 1-11 can be integrated in a smartphone, a tablet computer, a fixed location terminal device, a vehicle (e.g., an automobile), a wearable electronic device, a laptop computer, another device, or some combination thereof, as described in more detail below with reference to FIG. 22. In some other implementations, any of the packages of FIGS. 1-11 can be integrated into a mobile communication device, as described in more detail below with reference to FIG. 23.

FIGS. 12-14 illustrate examples of a top view of a substrate of implementations of the exemplary package 100 of FIG. 1. For example, each of FIGS. 12-14 includes a top view of an example of the first substrate 108 included in an implementation of the package 100 of FIG. 1 to show a respective illustrative layout of components and/or contacts on the first substrate 108. Each of the top views of the first substrate 108 of FIGS. 12-14 includes contacts 114D configured to be electrically coupled to the set of interconnects 120 of FIG. 1. Each of the top views of the first substrate 108 of FIGS. 12-14 also shows the first die 104 and the components 140 coupled to the first substrate 108.

Each of the top views of the first substrate 108 of FIGS. 12-14 also shows a position (e.g., a footprint) of the second die 206 (represented as a first dashed box) and a position (e.g., a footprint) of a heat sink 1202 (represented as a second dashed box) with respect to the first substrate 108. The heat sink 1202 may include or correspond to the heat sink 202 of FIG. 2 or 1002 of FIG. 10. The second die 206 may be coupled to the second substrate 110 of FIG. 1 that is configured to be electrically coupled to the first substrate 108 by the set of interconnects 120 of FIG. 1. The heat sink 1202 may be coupled to the second substrate 110 (as described at least with reference to FIG. 2-4 or 9-11) or to the first die 104 (as described at least with reference to FIG. 5-8).

It is noted that the position of the first die 104 is offset (in a horizontal direction along the X-axis) with respect to the second die 206 such that an entirety of the first die 104 does not overlap with the second die 206 in a vertical direction and an entirety of the second die 206 does not overlap with the first die 104 in the vertical direction (e.g., along the Z-axis). It is noted that in some implementations, the second die 206 may be included in a second package that is coupled to the package 100. Additionally, it is noted that the heat sink 1202 may be positioned above (in the vertical direction along the Z-axis) the first die 104 such that the heat sink 1202 overlaps with one or more hot spots of the first die 104 (e.g., a localized source of heat during operation of the first die 104).

In some implementations, the layout of the first substrate 108 of FIG. 12 may include or correspond to the package of FIG. 1, 2, 5, or 9-11. The layout of the first substrate 108 of FIG. 14 may include or correspond to the package of FIG. 4. Each of the top views of the first substrate 108 of FIGS. 12-14 are intended to be illustrative and non-limiting. Accordingly, additional layouts for the first substrate 108 are possible. For example, the layout of the first substrate 108 of FIG. 12 may include additional contacts 114D to the right of the first component 140A (e.g., to the right as shown along the X-axis), may not include the contacts 114D to the left of the first die 104, or a combination thereof.

Exemplary Sequence for Fabricating a Package Compatible with a Package Assembly Including Components Having an Offset Configuration

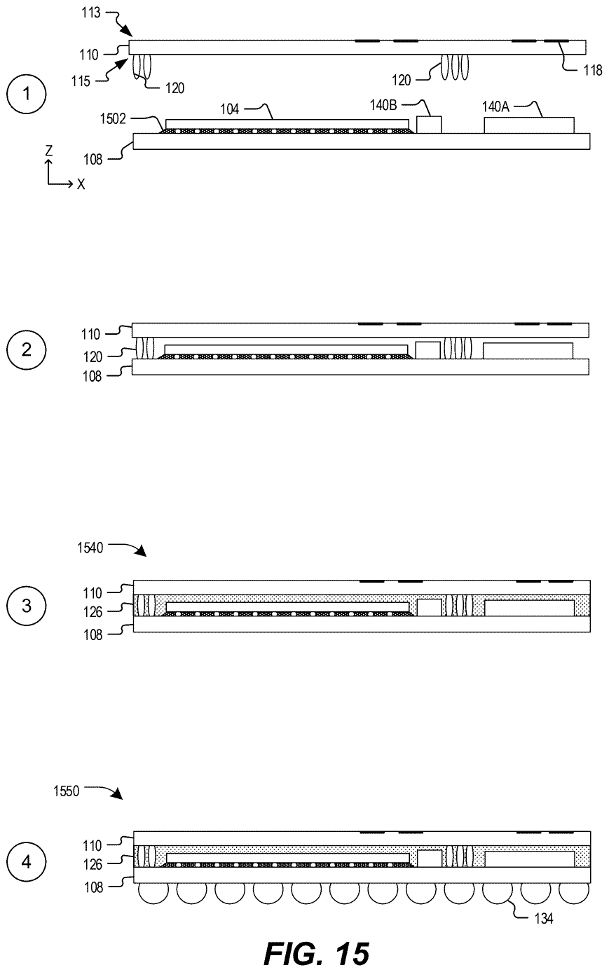

In some implementations, fabricating a package (e.g., any of the packages of FIGS. 1-14) compatible with a package assembly including components having an offset configuration includes several processes. Each of FIGS. 15-20 illustrates an exemplary sequence for fabricating or providing a package compatible with a package assembly including components having an offset configuration, as described with reference to any of FIGS. 1-14. In some implementations, the sequence of at least one of FIGS. 15-20 may be used to provide (e.g., during fabrication of) one or more of the packages of FIGS. 1-14.

It should be noted that the sequence of at least one of FIGS. 15-20 may combine one or more stages in order to simplify and/or clarify the sequence for providing or fabricating a package or a package assembly (e.g., a PoP). In some implementations, the order of the processes may be changed or modified. In some implementations, one or more of the processes may be replaced or substituted without departing from the scope of the disclosure. In the following description, reference is made to various illustrative Stages of the respective sequences, which are numbered (using circled numbers) in each of FIGS. 15-20. Each of the various stages of the sequence illustrated in each of FIGS. 15-20 shows a package compatible with package assembly including components having an offset configuration being formed.

FIG. 15 illustrates an exemplary sequence for fabricating an exemplary package compatible with a package assembly including components having an offset configuration. Stage 1 of FIG. 15 illustrates a state after providing the first substrate 108 and providing the second substrate 110. The first substrate 108 has the first die 104 and one or more components 140 coupled to the first substrate 108. Additionally, an underfill material is positioned between the first substrate 108 and the first die 104. The second substrate 110 is coupled to the set of interconnects 120.

Each of the first substrate 108 and the second substrate 110 includes multiple metal layers separated from one another by one or more dielectric layers and patterned to form contacts, traces, pads, etc. and interconnected by vias. In particular, the first substrate 108 may include contacts 114 or 916 (not shown), as illustrative, non-limiting examples. The second substrate 110 may include contacts 118, as an illustrative, non-limiting example. In some examples the second substrate 110 may also include contacts 1018 (not shown). Additionally, the first substrate 108, the second substrate 110, or both, can also include a solder resist layer or another protective layer or passivation layer through which various pads and/or contacts (e.g., off-package contacts) can be accessed.

Each of the first substrate 108 and the second substrate 110 can be formed using various lamination and patterning techniques. To illustrate, one or both of the substrates 108, 110 can be pre-formed, e.g., on a carrier. As an example, the first substrate 108 can be formed by forming a metal layer on a carrier. The metal layer can be patterned and covered with a dielectric layer. One or more vias can be formed through the dielectric layer to connect to the patterned metal layer, and another patterned metal layer can be formed on the dielectric layer. Formation of patterned metal layers, dielectric layers, and vias is repeated until all of the desired features of the first substrate 108 are formed, at which point the first substrate 108 can be removed from the carrier. Alternatively, operations, such as die attach operations to connect the first die 104 and/or the one or more components 140 to the first substrate 108 can be performed before the first substrate 108 is removed from the carrier. The second substrate 110 can be formed using similar techniques to those described above.

In this example, after formation of the first substrate 108, a print paste operation can be performed to apply solder paste on one or more contacts of the first substrate 108, and the first die 104 and/or the one or more components 140 can be attached to the first substrate 108. Additionally, after the first die 104 is attached to the first substrate 108, an underfill material 1502 can be deposited and an underfill cure operation can be performed to cure the underfill material 1502. After formation of the second substrate 110, the set of interconnects 120 can be formed on or attached to the second substrate 110 such that the second substrate 110 is electrically coupled to the set of interconnects 120. In some implementations, the set of interconnects 120 includes one or more copper pin structures, one or more copper cored ball structures, or a combination thereof.

Stage 2 illustrates a state after the set of interconnects 120 are coupled to the first substrate 108. For example, as part of Stage 2, a thermal compression bonding operation may be performed to couple, using the set of interconnects 120, the first substrate 108 and the second substrate 110. For example, the set of interconnects 120 can electrically couple the first substrate 108 and the second substrate 110.

Stage 3 illustrates a state after the encapsulant 126 is disposed between the first substrate 108 and the second substrate 110. Although the encapsulant 126 is described as being disposed between the first substrate 108 and the second substrate 110 after the first substrate 108 is coupled to the second substrate 110 using the set of interconnects 120, in other implementations, the encapsulant 126 can be deposited on the first substrate 108 prior to the first substrate 108 being coupled to the second substrate 110. After the encapsulant 126 is deposited on the first substrate 108 and after the first substrate 108 is coupled to the second substrate 110, the encapsulant 126 is positioned between the first substrate 108 and the second substrate 110 such that the encapsulant 126 occupies at least a portion of a space between the first substrate 108 and the second substrate 110. In some implementations, formation of a package 1540 (that is compatible for use in a package assembly, such as a PoP) is complete after Stage 3 of FIG. 15.

Stage 4 illustrates a state after formation of a BGA on the first substrate 108. Although described as a BGA, in other implementations, another conductive interconnect may be formed, such as pillars, bumps (e.g., microbumps), etc. The BGA may include one or more balls 134, such as one or more solder balls. For example, a BGA ball attach operation may be performed to couple the one or more balls 134 to the first substrate 108, such as to one or more second contacts 116 (not shown) on the second side 111 of the first substrate 108.

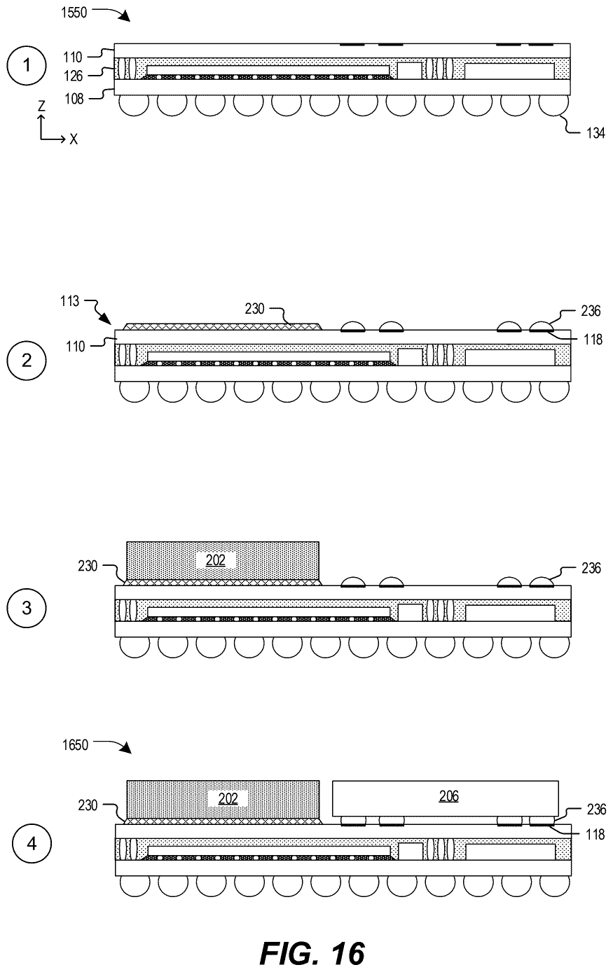

Formation of a package 1550 (e.g., a package for a package assembly) is complete after Stage 4 of FIG. 15. For example, the package 1550 may include or correspond to the package 100 of FIG. 1. However, in some implementations, the package 1550 can be used to form at least one of the packages of FIGS. 2-11. For example, one or more additional processes, as described with reference to one or more of FIGS. 16-20, may be performed on the package 1550 to form one of the packages of FIGS. 2-11.

Although certain Stages are illustrated in FIG. 15 in forming the package 1550, other processes can be included in the fabrication of the package 1550 without departing from the scope of the subject disclosure. For example, fabricating the package 1550 can include coupling a PMIC, such as the PMIC 920, or another component to the first substrate 108. To illustrate, the PMIC may be coupled on the second side 111 of the first substrate 108 prior to the formation of the BGA. As another example, multiple components (e.g., the component 140A and the component 140B) can be coupled to the first substrate 108 prior to or as part of Stage 1. It is also noted that in some implementations, the first substrate 108 and the second substrate 110 may be different sizes and/or the second substrate 110 may include an opening (e.g., a through channel) that extends between the first side 113 and the second side 115 of the second substrate 110. In some such implementations, the second substrate 110 or a portion thereof may not be positioned above (in the Z-direction) the first die 104, e.g., as depicted in FIGS. 5-8.

FIG. 16 illustrates an exemplary sequence for fabricating an exemplary package compatible with a package assembly including components having an offset configuration. Stage 1 of FIG. 16 illustrates a state after providing the package 1550. For example, as part of Stage 1, one or more operations described with reference to FIG. 15 may be performed to fabricate the package 1550.

Stage 2 illustrates a state after the adhesive material 230 and the solder 236 are deposited on the second substrate 110. For example, as part of Stage 2, the adhesive material 230 may be deposited on the first side 113 of the second substrate 110. As another example, as part of Stage 2, a paste print operation may be performed to deposit solder paste (including the solder 236) on one or more of the contacts 118 associated with the second substrate 110.

Stage 3 illustrates a state after the heat sink 202 is attached to the adhesive material 230 and an adhesive cure operation is performed to cure the adhesive material 230. In some implementations, the heat sink 202 may include or correspond to the heat sink 1202 of FIG. 12. Stage 4 illustrates a state after the second die 206 is attached to the solder 236 and a reflow operation is performed to couple (e.g., electrically and mechanically couple) the second die 206 to the one or more contacts 118. Although Stage 2 and Stage 4 describe the solder paste and the reflow operation, in other implementations the second die 206 may be electrically coupled to the one or more contacts 118 using a different technique, such as pad-to-pad bonding. In some implementations, the second die 206 is included in a package that is coupled to the contacts 118.

Formation of a package 1650 is complete after Stage 4 of FIG. 16. For example, the package 1650 may include or correspond to any of the packages of FIGS. 2-9. To illustrate, to form one of the packages of FIGS. 5-8, the adhesive material 230 may be deposited on a surface of one or more dies 104, a surface of the encapsulant 126, or a combination thereof. Additionally, to form the package 800 of FIG. 8, multiple heat sinks 202 can be coupled to the adhesive material 230. To form the package 900 of FIG. 9, the package 1550 can include a PMIC, such as the PMIC 920, or another component coupled to the first substrate 108. To illustrate, the PMIC may be coupled on the second side 111 of the first substrate 108 prior to the formation of the BGA.

Although certain Stages are illustrated in FIG. 16 in forming the package 1650, other processes can be included in the fabrication of the package 1650 without departing from the scope of the subject disclosure. For example, fabricating the package 1650 can include depositing a second underfill material between the second die 206 and the second substrate 110, and performing an underfill curing operation.

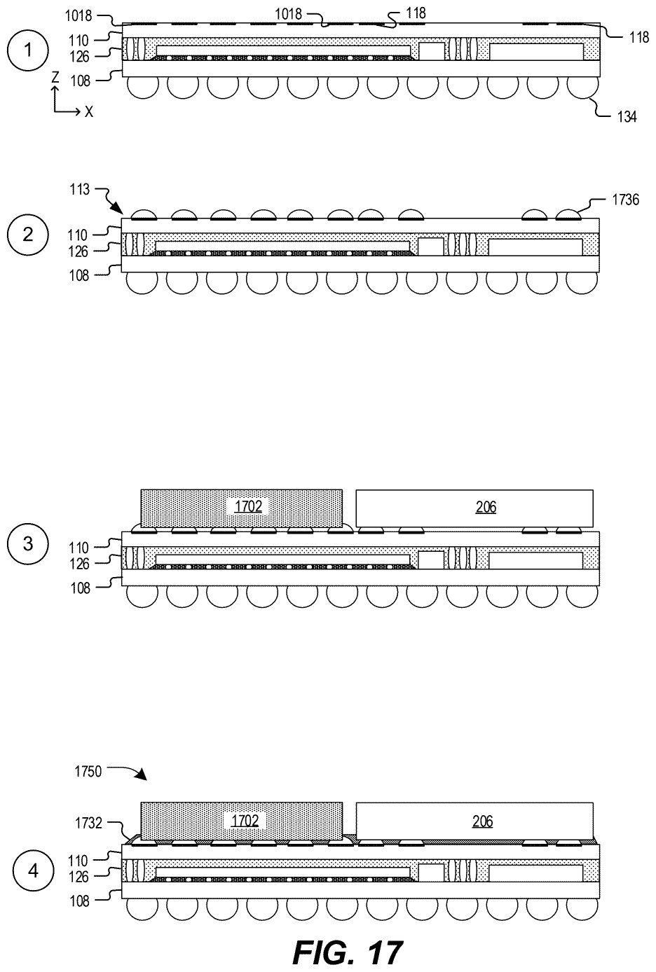

FIG. 17 illustrates an exemplary sequence for fabricating an exemplary package compatible with a package assembly including components having an offset configuration. Stage 1 of FIG. 17 illustrates a state after providing the package 1550. For example, as part of Stage 1, one or more operations described with reference to FIG. 15 may be performed to fabricate the package 1550. As shown, the second substrate 110 includes a first set of contacts 118 and a second set of contacts 1018. The first set of contacts 118 is configured to be coupled to the second die 206, and the second set of 1018 is configured to be coupled to a heat sink, as described further herein at least with reference to Stage 3 of FIG. 17.

Stage 2 illustrates a state after solder 1736 is deposited on the second substrate 110. For example, as part of Stage 2, a paste print operation may be performed to deposit solder paste (including the solder 1736) on one or more of the contacts 118 and 1018 associated with the second substrate 110. The solder 1736 may include or correspond to the solder 236 of FIG. 2 or the interconnect 1030 of FIG. 10.

Stage 3 illustrates a state after a heat sink 1702 and the second die 206 are attached to the solder 1736, and a reflow operation is performed to couple (e.g., electrically and fixedly couple) the second die 206 to the contacts 118 and to couple (e.g., thermally and fixedly couple) the heat sink 1702 to the contacts 1018. The heat sink 1702 may include or correspond to the heat sink 202, 1002, or 1202. In some implementations, the heat sink 1702 includes protrusions, such as the protrusions 1003 of FIG. 10.

Stage 4 illustrates a state after a second underfill material 1732 is deposited on the second substrate 110, and an underfill cure operation is performed to cure the second underfill material 1732. For example, the second underfill material 1732 may be deposited between the second substrate 110 and the heat sink 1702 and between the second substrate 110 and the second die 206. Although the second underfill material 1732 is described as being deposited between both the second substrate 110 and the heat sink 1702, and the second substrate 110 and the second die 206, in other implementations, the second underfill material 1732 may not be deposited or may be deposited between the second substrate 110 and one of the heat sink 1702 or the second die 206. In some implementations, the second underfill material 1732 includes a high-k underfill material. Additionally, or alternatively, in some implementations, the underfill cure operation may not be performed.

Formation of a package 1750 is complete after Stage 4 of FIG. 17. For example, the package 1750 may include or correspond to any of the package s of FIGS. 10-11. To form the package 1100 of FIG. 11, the package 1750 can include a PMIC, such as the PMIC 920, or another component coupled to the first substrate 108. To illustrate, the PMIC may be coupled on the second side 111 of the first substrate 108 prior to the formation of the BGA.

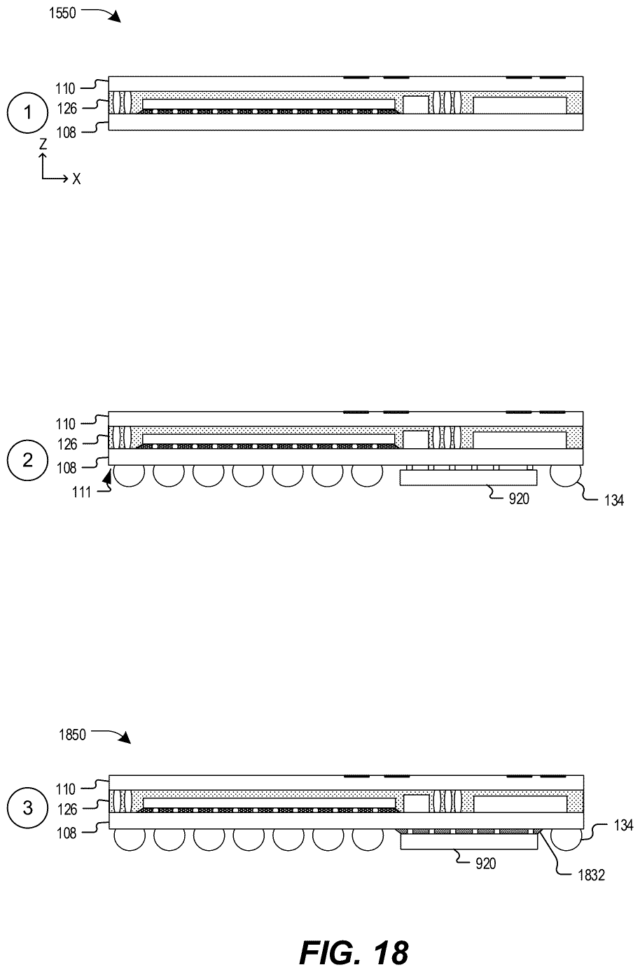

FIG. 18 illustrates an exemplary sequence for fabricating an exemplary package compatible with a package assembly including components having an offset configuration. Stage 1 of FIG. 18 illustrates a state after providing the package 1550. For example, as part of Stage 1, one or more operations described with reference to Stages 1-3 of FIG. 15 may be performed to fabricate the package 1550.

Stage 2 illustrates a state after a PMIC 920 is coupled (e.g., electrically coupled) to a set of contacts on the second side 111 of the first substrate 108, and formation of a BGA on the first substrate 108. The BGA may include one or more balls 134, such as one or more solder balls. For example, a BGA ball attach operation may be performed to couple the one or more balls 134 to the first substrate 108, such as to one or more second contacts 116 (not shown) on the second side 111 of the first substrate 108. Although described as a BGA, in other implementations, another conductive interconnect may be formed, such as pillars, bumps (e.g., microbumps), etc. It is noted that although the second side 111 of the first substrate 108 is described as being coupled to the PMIC 920, the PMIC 920 may optionally be replaced with another component, such as a die, a microcontroller, an ASIC, an FPGA, a CPU, a memory device, a modem, an RF device (e.g., one or more amplifiers), an LED integrated device, and/or an MEM device (e.g., an SAW filter, a BAW filter), or a passive device, as illustrative, non-limiting examples.

Stage 3 illustrates a state after a third underfill material 1832 is deposited on the first substrate 108, and an underfill cure operation is performed to cure the third underfill material 1832. For example, the third underfill material 1832 may be deposited between the first substrate 108 and the PMIC 920. Although the third underfill material 1832 is described as being deposited, in other implementations, the third underfill material 1832 may not be deposited.

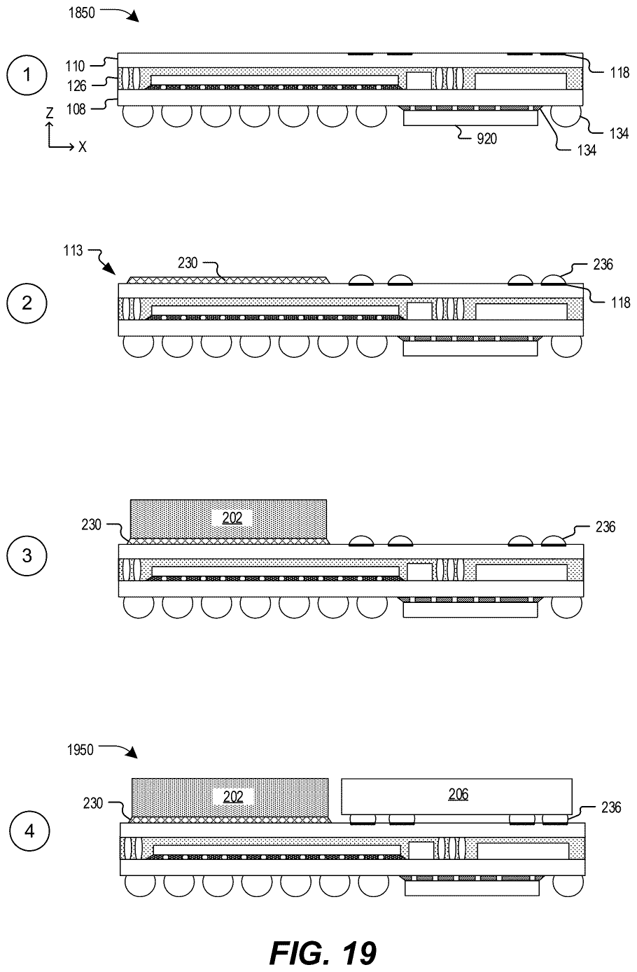

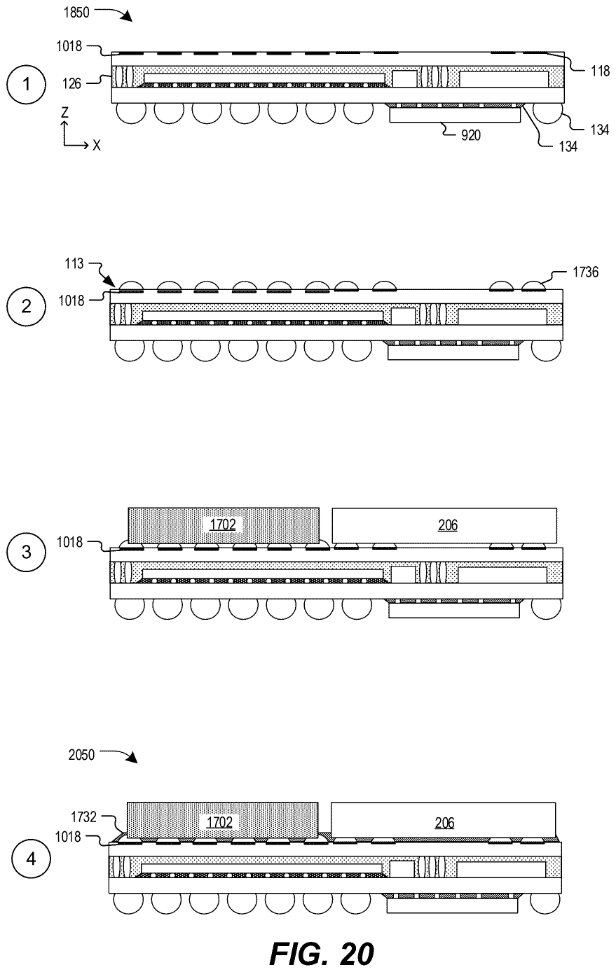

Formation of a package 1850 is complete after Stage 3 of FIG. 18. The package 1850 may be associated with or included in any of the packages of FIG. 9 or 11. To illustrate, one or more additional fabrication stages may be performed to fabricate the package of FIG. 9, as further described with reference to FIG. 19, or the package of FIG. 11, as further described with reference to FIG. 20.

FIG. 19 illustrates an exemplary sequence for fabricating an exemplary package compatible with a package assembly including components having an offset configuration. Stage 1 of FIG. 19 illustrates a state after providing the package 1850. For example, as part of Stage 1, one or more operations described with reference to FIG. 18 may be performed to fabricate the package 1850. As shown, the second substrate 110 includes a first set of contacts 118 configured to be coupled to the second die 206.

Stage 2 illustrates a state after the adhesive material 230 and the solder 236 are deposited on the second substrate 110. For example, as part of Stage 2, the adhesive material 230 may be deposited on the first side 113 of the second substrate 110. In some implementations in which the second substrate 110 is not above the first die 104, at Stage 2, the adhesive material 230 may be deposited on a surface of one or more dies 104, a surface of the encapsulant 126, or a combination thereof. As another example, as part of Stage 2, a paste print operation may be performed to deposit solder paste (including the solder 236) on one or more of the contacts 118 associated with the second substrate 110.

Stage 3 illustrates a state after the heat sink 202 is attached to the adhesive material 230 and an adhesive cure operation is performed to cure the adhesive material 230. Stage 4 illustrates a state after the second die 206 is attached to the solder 236 and a reflow operation is performed to couple (e.g., electrically and fixedly couple) the second die 206 to the one or more contacts 118.

Formation of a package 1950 is complete after Stage 4 of FIG. 19. For example, the package 1950 may include or correspond to the package of FIG. 9.

Although certain Stages are illustrated in FIG. 19 in forming the package 1950, other processes can be included in the fabrication of the package 1950 without departing from the scope of the subject disclosure. For example, fabricating the package 1950 can include depositing a second underfill material between the second die 206 and the second substrate 110, and performing an underfill curing operation.

FIG. 20 illustrates an exemplary sequence for fabricating an exemplary package compatible with a package assembly including components having an offset configuration. Stage 1 of FIG. 20 illustrates a state after providing the package 1850. For example, as part of Stage 1, one or more operations described with reference to FIG. 18 may be performed to fabricate the package 1850. As shown, the second substrate 110 includes a first set of contacts 118 and a second set of contacts 1018. The first set of contacts 118 is configured to be coupled to the second die 206, and the second set of 1018 is configured to be coupled to a heat sink, as described further herein at least with reference to Stage 3 of FIG. 20.

Stage 2 illustrates a state after solder 1736 is deposited on the second substrate 110. For example, as part of Stage 2, a paste print operation may be performed to deposit solder paste (including the solder 1736) on one or more of the contacts 118 and 1018 associated with the second substrate 110. The solder 1736 may include or correspond to the solder 236 of FIG. 2 or the interconnect 1030 of FIG. 10.

Stage 3 illustrates a state after a heat sink 1702 and the second die 206 are attached to the solder 1736, and a reflow operation is performed to couple (e.g., electrically and fixedly couple) the second die 206 to the contacts 118 and to couple (e.g., thermally and fixedly couple) the heat sink 1702 to the contacts 1018. The heat sink 1702 may include or correspond to the heat sink 202, 1002, or 1202. In some implementations, the heat sink 1702 includes protrusions, such as the protrusions 1003 of FIG. 10.

Stage 4 illustrates a state after a second underfill material 1732 is deposited on the second substrate 110, and an underfill cure operation is performed to cure the second underfill material 1732. For example, the second underfill material 1732 may be deposited between the second substrate 110 and the heat sink 1702 and between the second substrate 110 and the second die 206. Although the second underfill material 1732 is described as being deposited between both the second substrate 110 and the heat sink 1702, and the second substrate 110 and the second die 206, in other implementations, the second underfill material 1732 may not be deposited or may be deposited between the second substrate 110 and one of the heat sink 1702 or the second die 206. In some implementations, the second underfill material 1732 includes a high-k underfill material. Additionally, or alternatively, in some implementations, the underfill cure operation may not be performed.

Formation of a package 2050 is complete after Stage 4 of FIG. 20. For example, the package 2050 may include or correspond to the package of FIG. 11.

Exemplary Flow Diagram of a Method for Fabricating a Package Compatible with a Package Assembly Including Components Having an Offset Configuration

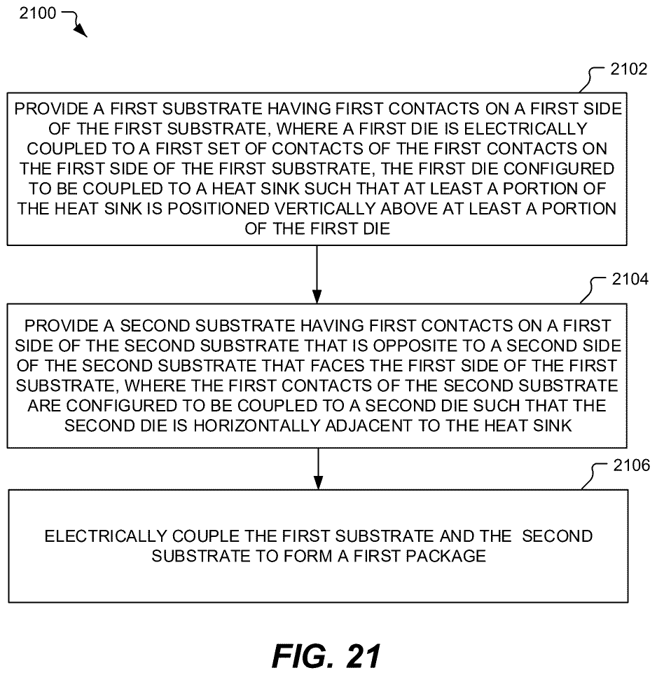

In some implementations, fabricating a package compatible with a package assembly including components having an offset configuration includes several processes. FIG. 21 illustrates an exemplary flow diagram of a method 2100 of fabricating an illustrative package compatible with a package assembly including components having an offset configuration. In a particular aspect, one or more operations of the method 2100 are performed by one or more processors of a fabrication system. In some implementations, operations of the method 2100 may be stored as instructions by a non-transitory computer-readable storage medium, and the instructions may be executable by at least one processor to cause the at least one processor to perform operations of the method 2100. In some implementations, the method 2100 of FIG. 21 may be used to provide or fabricate any of the packages of FIGS. 1-20.

It should be noted that the method 2100 of FIG. 21 may combine one or more processes in order to simplify and/or clarify the method for providing or fabricating an integrated circuit device, a package, or a PoP. In some implementations, the order of the processes may be changed or modified.

The method 2100 includes providing a first substrate having first contacts on a first side of the first substrate, at block 2102. For example, at Stage 1 of FIG. 15, the first substrate 108 is provided. The first side of the first substrate and the first contact may include or correspond to the first side 109 of the first substrate 108 and the first contacts 114. In some implementations, the first substrate 108 includes a package substrate. In some implementations, a second side of the first substrate is opposite to the first side of the substrate and has first contacts. For example, the second side and the first contacts may include or correspond to the second side 111 and the contacts 116.

In some implementations, a first die is electrically coupled to a first set of contacts of the first contacts on the first side of the first substrate. The first die and the first set of contacts may include or correspond to the first die 104 and the first set of contacts 114A. The first die is configured to be coupled to a heat sink such that at least a portion of the heat sink is positioned vertically above at least a portion of the first die. For example, the heat sink may include or correspond to the heat sink 1002, 1202, or 1702.

In some implementations, a first component may be electrically coupled to a second set of contacts of the first contacts on the first side of the first substrate. The first component may include or correspond to the component 140. The second set of contacts may include or correspond to the set of contacts 114C or 114B.

At block 2104, the method 2100 includes providing a second substrate having first contacts on a first side of the second substrate that is opposite to a second side of the second substrate that faces the first side of the first substrate. For example, at Stage 1 of FIG. 15, the second substrate 110 is provided. The first contacts on the first side of the second substrate can include or correspond to the contacts 118 on the first side 113 of the second substrate 110. The first contacts of the second substrate are configured to be coupled to a second die, such as the second die 206. To illustrate, the first contacts are configured to be coupled to a second die such that the second die is horizontally adjacent to the heat sink. In some implementations, the second substrate has second contacts on a second side of the second substrate, which can include or correspond to the contacts 119 on the second side 115 of the second substrate. In some implementations, the second substrate includes an interposer or a laminate substrate.

At block 2106, the method 2100 includes electrically coupling the first substrate to the second substrate to form a first package. For example, at Stage 2 of FIG. 15, the first substrate 108 is electrically coupled to the second substrate 110. The first package may include or correspond to the package 100, 1540, 1550, or 1850.

In some implementations, a set of interconnects is coupled to the second side of the second substrate. For example, the set of interconnects may include or correspond to the set of interconnects 120 coupled to the second side 115 of the second substrate 110. In some such implementations, the method 2100 includes coupling the set of interconnects of the second substrate to the first substrate such that the second side of the second substrate faces the first side of the first substrate and to electrically couple the first substrate and the first contacts of the second substrate. For example, at Stage 2 of FIG. 15, the set of interconnects 120 (that are coupled to the second substrate 110) are coupled to the first substrate 108 such that the second side 115 of the second substrate 110 faces the first side 109 of the first substrate 108.

In some implementations, the method 2100 also includes depositing an encapsulant positioned between the first substrate and the second substrate. For example, at Stage 3 of FIG. 15, the encapsulant 126 is deposited between the first substrate 108 and the second substrate 110. The encapsulant may be in contact with the second substrate. For example, the encapsulant 126 may be in contact with the second substrate 110.

In some implementations, the method 2100 also includes coupling package interconnects to a second side of the first substrate. For example, at Stage 4 of FIG. 15, the balls 134 are coupled to the second contacts 116 on the second side 111 of the first substrate 108. Additionally, or alternatively, the method 2100 may include coupling another component to the second side of the first substrate. For example, at Stage 2 of FIG. 18, the PMIC 920 is coupled to the second side 111 of the first substrate 108. Alternatively, a device other than a PMIC may be coupled to the second side of the first substrate.

In some implementations, the method 2100 also includes depositing an adhesive material on the first side of the second substrate or on the first die. For example, at Stage 2 of FIG. 16 or at Stage 2 of FIG. 19, the adhesive material 230 is deposited on the first side 113 of the second substrate 110 or on the first die 104. As another example, the adhesive material 230 may be deposited on the first die 104.

In some implementations, the method 2100 also includes coupling the heat sink to the adhesive material to thermally couple the heat sink to the first die. For example, at Stage 3 of FIG. 16 or at Stage 3 of FIG. 19, the heat sink 202 is coupled to the adhesive material 230.

In some implementations, the method 2100 also includes coupling protrusions of the heat sink to at least one contact on the first side of the second substrate to thermally couple the heat sink to the first die. For example, the heat sink 1002, 1202, or 1702 may include protrusions 1003 that are coupled to contacts 1018.

In some implementations, the method 2100 also includes coupling the second die to the first contacts on the first side of the second substrate. For example, the second die 206 is coupled to the contacts 118 at Stage 4 of FIG. 16, Stage 3 of FIG. 17, Stage 4 of FIG. 19, or Stage 3 of FIG. 20.

It is noted that one or more blocks (or operations) described with reference to FIG. 21 may be combined with one or more blocks (or operations) described with reference to another of the figures. For example, one or more blocks (or operations) of FIG. 21 may be combined with one or more blocks (or operations) of FIGS. 15-20. Additionally, or alternatively, one or more operations described above with reference to FIGS. 1-21 may be combined with one or more operations described with reference to FIG. 22 or 23.

### Exemplary Electronic Devices

FIG. 22 illustrates various electronic devices that may include or be integrated with any of the packages of FIGS. 1-21. For example, a mobile phone device 2202, a laptop computer device 2204, a fixed location terminal device 2206, a wearable device 2208, or a vehicle 2210 (e.g., an automobile or an aerial device) may include a device 2200. The device 2200 can include, for example, any of the packages of FIGS. 1-21 described herein. The devices 2202, 2204, 2206 and 2208 and the vehicle 2210 illustrated in FIG. 22 are merely exemplary. Other electronic devices may also feature the device 2200 including, but not limited to, a group of devices (e.g., electronic devices) that includes mobile devices, hand-held PCS units, portable data units such as personal digital assistants, GPS enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), VR devices, AR devices, XR devices, data center components, vehicles, mobile location data units, mobile phones, cellular phones, SiP phones, phablets, a portable computer, mobile computing devices, wearable computing devices, monitors, computer monitors, televisions, tuners, radios, satellite radios, digital music players, portable music players, digital video players, DVD players, portable digital video players, automobiles, vehicle components, avionics systems, drones, multicopters, or any other device that stores or retrieves data or computer instructions, or any combination thereof.

FIG. 23 illustrates a block diagram of a particular electronic device 2300 that may integrate an exemplary package 2350 having or that supports an offset configuration as described herein. For example, the package 2350 includes or corresponds to any of the packages as described with reference to FIGS. 1-22. The device 2300 may include or correspond to or be integrated in one or more of the devices 2202, 2204, 2206, or 2208 or the vehicle 2210 (or a device within the vehicle 2210).

The device 2300 includes a housing 2302. The housing 2302 may include or define at least a portion of an outer structure of the device 2300. The device 2300 may also include a display 2304, a heat spreader 2306, a frame 2308, the package 2350, and a cover 2310. In some implementations, the housing 2302 may include the display 2304, the frame 2308, the cover 2310 (e.g., a front cover or a back cover), one or more panels (e.g., a front panel or a back panel), or a combination thereof.

The display 2304 may be coupled to the heat spreader 2306. The heat spreader 2306 may be coupled to the frame 2308, such as a middle frame. In some implementations, the heat spreader 2306 is positioned between the display 2304 and the frame 2308.

The package 2350 may be coupled to the frame 2308. In some implementations, the package 2350 is coupled to the frame 2308 such that a heat sink (e.g., the heat sink 202, 1002, 1202, or 1702) of (or coupled to) the package 2350 is coupled to or in contact with the heat spreader 2306. Additionally, or alternatively, the package 2350 may include a PMIC, such as the PMIC 920.

The cover 2310, such as a back cover, may be coupled to the frame 2308, a printed circuit board (PCB), or a combination thereof. For example, in some implementations, the device 2300 includes a PCB coupled to the frame. In some such implementations, a PMIC may be coupled to the PCB.

One or more of the components, processes, features, and/or functions illustrated in FIGS. 1-23 may be rearranged and/or combined into a single component, process, feature or function or embodied in several components, processes, or functions. Additional elements, components, processes, and/or functions may also be added without departing from the disclosure. It should also be noted FIGS. 1-23 and its corresponding description in the present disclosure is not limited to dies and/or ICs. In some implementations, FIGS. 1-23 and its corresponding description may be used to manufacture, create, provide, and/or produce devices and/or integrated devices. In some implementations, a device may include a die, an integrated device, an embedded multi-chip package, an integrated passive device (IPD), a die package, an IC device, a device package, an IC package, a wafer, a semiconductor device, a package-on-package (PoP) (e.g., a package assembly), a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling or electrical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third”, and “fourth” (and/or anything above fourth) is arbitrary. Any of the components described may be the first component, the second component, the third component or the fourth component. For example, a component that is referred to as a second component, may be the first component, the second component, the third component or the fourth component.

The terms “encapsulate”, “encapsulating”, and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component.

A value that is about X-XX, may mean a value that is between X and XX, inclusive of X and XX. The value(s) between X and XX may be discrete or continuous. The term “about ‘value X’”, or “approximately ‘value X’”, as used in the disclosure means within 10 percent of the ‘value X’. For example, a value of about 1 or approximately 1, would mean a value in a range of 0.9-1.1. The term “substantially” is defined as largely but not necessarily wholly what is specified (and includes what is specified; for example, substantially 90 degrees includes 90 degrees and substantially parallel includes parallel), as understood by a person of ordinary skill in the art. In any disclosed implementations, the term “substantially” may be substituted with “within [a percentage] of” what is specified, where the percentage includes 0.1, 1, 5, or 10 percent. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a package includes: a first substrate having first contacts on a first side of the first substrate; a first die electrically coupled to a first set of contacts of the first contacts on the first side of the first substrate, the first die is configured to be coupled to a heat sink such that at least a portion of the heat sink is positioned vertically above at least a portion of the first die; and a second substrate above and electrically coupled to the first substrate, the second substrate having first contacts on a first side of the second substrate that is opposite to a second side of the second substrate that faces the first side of the first substrate, where the first contacts of the second substrate are configured to be electrically coupled to a second die such that the second die is horizontally adjacent to the heat sink.

Example 2 includes the package of Example 1, where: the first substrate includes a package substrate, and the second substrate includes an interposer or a laminate substrate.

Example 3 includes the package of Example 1 or Example 2, and further includes a first component electrically coupled to a second set of contacts of the first contacts on the first side of the first substrate, wherein the first component and the first die are positioned side-by-side on the first side of the first substrate.

Example 4 includes the package of Example 3, where the first contacts on the first side of the second substrate define a footprint that is above the first component.

Example 5 includes the package of Example 3 or Example 4, where: the first die includes a processor; and the first component includes a modem.

Example 6 includes the package of any of Examples 3 to 5, and further includes an encapsulant that at least partially surrounds the first die and the first component, where the encapsulant is positioned between the first substrate and the second substrate.

Example 7 includes the package of any of Examples 3 to 6, and further includes a set of interconnects positioned between the first substrate and the second substrate.

Example 8 includes the package of Example 7, where: the set of interconnects includes a first interconnect and a second interconnect; the first interconnect is positioned between the first die and the first component; and the first die is positioned between the first interconnect and the second interconnect.

Example 9 includes the package of Example 7, where: the set of interconnects includes a first interconnect and a second interconnect; the first interconnect is positioned between the first die and the first component; and the first component is positioned between the first interconnect and the second interconnect.

Example 10 includes the package of Example 7, where: the set of interconnects includes a first interconnect, a second interconnect, and a third interconnect; the first interconnect is positioned between the first die and the first component; the first die is positioned between the first interconnect and the second interconnect; and the first component is positioned between the first interconnect and the third interconnect.

Example 11 includes the package of any of Examples 1 to 10, where the second substrate defines a first opening on the first side of the second substrate, a second opening on the second side of the second substrate, and a channel that extends between the first opening and the second opening.

Example 12 includes the package of any of Examples 1 to 11, where the first side of the first substrate has a first area that is greater than a second area of the first side of the second substrate.

Example 13 includes the package of any of Examples 1 to 12, and further includes first underfill material positioned between the first substrate and the first die.

Example 14 includes the package of any of Examples 3 to 13, and further includes a passive device electrically coupled to a third set of contacts on the first side of the first substrate.

Example 15 includes the package of Example 14, where: the passive device is positioned between the first die and the first component, or the first die is positioned between the passive device and the first component.

Example 16 includes the package of any of Examples 1 to 15, and further includes the heat sink thermally coupled to the first die, and where the first die is positioned between the heat sink and the first substrate.

Example 17 includes the package of Example 16, where the heat sink thermally coupled to the first die is configured to be positioned side-by-side with the second die coupled to the first contacts on the first side of the second substrate.

Example 18 includes the package of Example 16 or Example 17, where the heat sink is thermally coupled to the first die with an adhesive material, and where the adhesive material is positioned between the heat sink and the first die.

Example 19 includes the package of Example 18, where the adhesive material is positioned on the first side of the second substrate in a space above the upper side of the first die.

Example 20 includes the package of Example 18 or Example 19, where the adhesive material is positioned on at least a portion of the upper side of the first die.

Example 21 includes the package of Example 20, where the adhesive material is positioned on an upper side of an encapsulant that is in a space above the upper side of the first die.

Example 22 includes the package of Example 16, where the heat sink has protrusions, and where the protrusions are thermally coupled, via contacts of the second substrate, to the first die.

Example 23 includes the package of Example 22, and further includes second underfill material positioned between the heat sink and the second substrate.

Example 24 includes the package of Example 16, and further includes another component electrically coupled to a third set of contacts of the first contacts on the first side of the first substrate.

Example 25 includes the package of Examples 24, and further includes multiple heat sinks that include the heat sink, where the other component is thermally coupled to at least one heat sink of the multiple heat sinks, and where the other component is positioned between the at least one heat sink and the first substrate.

Example 26 includes the package of any of Examples 1 to 25, and further includes the second die coupled to the first side of the second substrate.

Example 27 includes the package of any of Examples 1 to 26, where the first die includes a first chiplet, and where the second die includes a second chiplet.

Example 28 includes the package of any of Examples 1 to 27, and further includes a second package coupled to the first side of the second substrate, the second package includes the second substrate.

Example 29 includes the package of any of Examples 1 to 28, where the first substrate has second contacts on a second side of the first substrate that is opposite to the first side of the first substrate.

Example 30 includes the package of Example 29, and further includes a device, where the device includes a power management integrated circuit (PMIC) coupled to the second side of the first substrate.

Example 31 includes the package of any of Examples 1 to 30, further includes a frame coupled to the second substrate; and a cover coupled to the frame.

Example 32 includes the package of Example 31, where the frame includes a middle frame structure.

Example 33 includes the package of Example 31 or Example 32, further includes a heat spreader coupled to the heat sink, the frame, or a combination thereof; and a display screen coupled to the heat spreader, where the heat spreader is positioned between the display screen and the heat sink.

Example 34 includes the package of Example 33, where the package includes a portable communication device.

Example 35 includes the package of any of Examples 1 to 34, where the package is integrated within a mobile device, a hand-held personal communication system (PCS) unit, a portable data unit, a global positioning system (GPS) enabled device, a navigation device, a set top box, a music player, a video player, an entertainment unit, a virtual reality (VR) device, an augmented reality (AR) device, an extended reality (XR) device, a fixed location data unit, a communications device, a smartphone, a tablet computer, a computer, a wearable device, an Internet of things (IoT) device, a data center component, a server, a router, a vehicle, a mobile location data unit, a mobile phone, a cellular phone, a session initiation protocol (SiP) phone, a phablet, a portable computer, a mobile computing device, a wearable computing device, a personal digital assistant (PDA), a monitor, a computer monitor, a television, a tuner, a radio, a satellite radio, a digital music player, a portable music player, a digital video player, a digital video disc (DVD) player, a portable digital video player, an automobile, a vehicle component, avionics systems, a drone, a multicopter, or a combination thereof.

According to Example 36, a method of fabrication includes providing a first substrate having first contacts on a first side of the first substrate, where a first die is electrically coupled to a first set of contacts of the first contacts on the first side of the first substrate, where the first die is configured to be coupled to a heat sink such that at least a portion of the heat sink is positioned vertically above at least a portion of the first die; providing a second substrate having first contacts on a first side of the second substrate that is opposite to a second side of the second substrate that faces the first side of the first substrate, wherein the first contacts of the second substrate are configured to be electrically coupled to a second die such that the second die is horizontally adjacent to the heat sink; and electrically coupling the first substrate and the second substrate to form a first package.

Example 37 includes the method of Example 36, where a first component is electrically coupled to a second set of contacts of the first contacts on the first side of the first substrate.

Example 38 includes the method of Example 36 or Example 37, where a set of interconnects is coupled to the second side of the second substrate.

Example 39 includes the method of Example 38, where electrically coupling the first substrate and the second substrate includes electrically coupling the set of interconnects to a third set of contacts of the first contacts on the first side of the first substrate.

Example 40 includes the method of any of Examples 36 to 39, and further includes depositing an encapsulant between the first substrate and the second substrate, the encapsulant in contact with the second substrate.

Example 41 includes the method of any of Examples 36 to 40, where a second side of the first substrate is coupled to second contacts, and where the second side of the first substrate is opposite to the first side of the first substrate.

Example 42 includes the method of Example 41, and further includes coupling another component to the second side of the first substrate.

Example 43 includes the method of Example 41 or Example 42, and further includes coupling package contacts to a second side of the first substrate.

Example 44 includes the method of any of Examples 36 to 43, further includes depositing an adhesive material on at least one of the first side of the second substrate or on the first die; and coupling the heat sink to the adhesive material to thermally couple the heat sink to the first die.

Example 45 includes the method of any of Examples 36 to 44, and further includes coupling protrusions of the heat sink to at least one contact on the first side of the second substrate to thermally couple the heat sink to the first die.

Example 46 includes the method of any of Examples 36 to 45, and further includes coupling the second die to the first contacts on the first side of the second substrate to form a package assembly.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A package comprising:
a first substrate having first contacts on a first side of the first substrate;
a first die electrically coupled to a first set of contacts of the first contacts on the first side of the first substrate, wherein the first die is configured to be coupled to a heat sink such that at least a portion of the heat sink is positioned vertically above at least a portion of the first die; and
a second substrate above and electrically coupled to the first substrate, the second substrate having first contacts on a first side of the second substrate that is opposite to a second side of the second substrate that faces the first side of the first substrate,
wherein the first contacts of the second substrate are configured to be electrically coupled to a second die such that the second die is horizontally adjacent to the heat sink.

2. The package of claim 1, wherein:
the first substrate comprises a package substrate, and
the second substrate comprises an interposer or a laminate substrate.

3. The package of claim 1, further comprising a first component electrically coupled to a second set of contacts of the first contacts on the first side of the first substrate, wherein the first component and the first die are positioned side-by-side on the first side of the first substrate.

4. The package of claim 3, wherein the first contacts on the first side of the second substrate define a footprint that is above the first component.

5. The package of claim 3, wherein:
the first die comprises a processor; and
the first component comprises a modem.

6. The package of claim 3, further comprising an encapsulant that at least partially surrounds the first die and the first component, wherein the encapsulant is positioned between the first substrate and the second substrate.

7. The package of claim 3, further comprising a set of interconnects positioned between the first substrate and the second substrate.

8. The package of claim 7, wherein:
the set of interconnects includes a first interconnect and a second interconnect;
the first interconnect is positioned between the first die and the first component; and
the first die is positioned between the first interconnect and the second interconnect.

9. The package of claim 7, wherein:
the set of interconnects includes a first interconnect and a second interconnect;
the first interconnect is positioned between the first die and the first component; and
the first component is positioned between the first interconnect and the second interconnect.

10. The package of claim 7, wherein:
the set of interconnects includes a first interconnect, a second interconnect, and a third interconnect;
the first interconnect is positioned between the first die and the first component;
the first die is positioned between the first interconnect and the second interconnect; and
the first component is positioned between the first interconnect and the third interconnect.

11. The package of claim 1, wherein the second substrate defines a first opening on the first side of the second substrate, a second opening on the second side of the second substrate, and a channel that extends between the first opening and the second opening.

12. The package of claim 1, wherein the first side of the first substrate has a first area that is greater than a second area of the first side of the second substrate.

13. The package of claim 1, further comprising first underfill material positioned between the first substrate and the first die.

14. The package of claim 3, further comprising a passive device electrically coupled to a third set of contacts on the first side of the first substrate.

15. The package of claim 14, wherein:
the passive device is positioned between the first die and the first component, or
the first die is positioned between the passive device and the first component.

16. The package of claim 1, further comprising the heat sink thermally coupled to the first die, and wherein the first die is positioned between the heat sink and the first substrate.

17. The package of claim 16, wherein the heat sink thermally coupled to the first die is configured to be positioned side-by-side with the second die coupled to the first contacts on the first side of the second substrate.

18. The package of claim 1, wherein the heat sink is thermally coupled to the first die with an adhesive material, and wherein the adhesive material is positioned between the heat sink and the first die.

19. The package of claim 18, wherein the adhesive material is positioned on the first side of the second substrate in a space above the upper side of the first die.

20. The package of claim 18, wherein the adhesive material is positioned on at least a portion of the upper side of the first die.

21. The package of claim 20, wherein the adhesive material is positioned on an upper side of an encapsulant that is in a space above the upper side of the first die.

22. The package of claim 1, wherein the heat sink has protrusions, and wherein the protrusions are thermally coupled, via contacts of the second substrate, to the first die.

23. The package of claim 22, further comprising second underfill material positioned between the heat sink and the second substrate.

24. The package of claim 1, further comprising another component electrically coupled to a third set of contacts of the first contacts on the first side of the first substrate.

25. The package of claim 24, further comprising multiple heat sinks that include the heat sink, wherein the other component is thermally coupled to at least one heat sink of the multiple heat sinks, and wherein the other component is positioned between the at least one heat sink and the first substrate.

26. The package of claim 1, further comprising the second die coupled to the first side of the second substrate.

27. The package of claim 26, wherein the first die includes a first chiplet, and wherein the second die includes a second chiplet.

28. The package of claim 26, further comprising a second package coupled to the first side of the second substrate, the second package includes the second die.

29. The package of claim 1, wherein the first substrate has second contacts on a second side of the first substrate that is opposite to the first side of the first substrate.

30. The package of claim 29, further comprising a device, wherein the device includes a power management integrated circuit (PMIC) coupled to the second side of the first substrate.

31. The package of claim 1, further comprising:
a frame coupled to the second substrate; and
a cover coupled to the frame.

32. The package of claim 31, wherein the frame includes a middle frame structure.

33. The package of claim 31, further comprising:
a heat spreader coupled to the heat sink, the frame, or a combination thereof; and
a display screen coupled to the heat spreader,
wherein the heat spreader is positioned between the display screen and the heat sink.

34. The package of claim 33, wherein the package includes a portable communication device.

35. The package of claim 1, wherein the package is integrated within a mobile device, a hand-held personal communication system (PCS) unit, a portable data unit, a global positioning system (GPS) enabled device, a navigation device, a set top box, a music player, a video player, an entertainment unit, a virtual reality (VR) device, an augmented reality (AR) device, an extended reality (XR) device, a fixed location data unit, a communications device, a smartphone, a tablet computer, a computer, a wearable device, an Internet of things (IoT) device, a data center component, a server, a router, a vehicle, a mobile location data unit, a mobile phone, a cellular phone, a session initiation protocol (SiP) phone, a phablet, a portable computer, a mobile computing device, a wearable computing device, a personal digital assistant (PDA), a monitor, a computer monitor, a television, a tuner, a radio, a satellite radio, a digital music player, a portable music player, a digital video player, a digital video disc (DVD) player, a portable digital video player, an automobile, a vehicle component, avionics systems, a drone, a multicopter, or a combination thereof.

36. A method of fabrication comprising:
providing a first substrate having first contacts on a first side of the first substrate, wherein a first die is electrically coupled to a first set of contacts of the first contacts on the first side of the first substrate, and wherein the first die is configured to be coupled to a heat sink such that at least a portion of the heat sink is positioned vertically above at least a portion of the first die;
providing a second substrate having first contacts on a first side of the second substrate that is opposite to a second side of the second substrate that faces the first side of the first substrate, wherein the first contacts of the second substrate are configured to be electrically coupled to a second die such that the second die is horizontally adjacent to the heat sink; and
electrically coupling the first substrate and the second substrate to form a first package.

37. The method of claim 36, wherein a first component is electrically coupled to a second set of contacts of the first contacts on the first side of the first substrate.

38. The method of claim 36, wherein a set of interconnects is coupled to the second side of the second substrate.

39. The method of claim 38, wherein electrically coupling the first substrate and the second substrate includes electrically coupling the set of interconnects to a third set of contacts of the first contacts on the first side of the first substrate.

40. The method of claim 36, further comprising depositing an encapsulant between the first substrate and the second substrate, the encapsulant in contact with the second substrate.

41. The method of claim 36, wherein a second side of the first substrate is coupled to second contacts, and wherein the second side of the first substrate is opposite to the first side of the first substrate.

42. The method of claim 41, further comprising coupling another component to the second side of the first substrate.

43. The method of claim 41, further comprising coupling package contacts to the second side of the first substrate.

44. The method of claim 36, further comprising:
depositing an adhesive material on at least one of the first side of the second substrate or on the first die; and
coupling the heat sink to the adhesive material to thermally couple the heat sink to the first die.

45. The method of claim 36, further comprising coupling protrusions of the heat sink to at least one contact on the first side of the second substrate to thermally couple the heat sink to the first die.

46. The method of claim 36, further comprising coupling the second die to the first contacts on the first side of the second substrate to form a package assembly.
